(19) United States
(12) Patent Application Publication
(10) Pub. No.: US 2007/0093005 A1
(43) Pub. Date: Apr. 26, 2007

(54) Thin film transistor panel and method of manufacture

(76) Inventors: Joo-Han Kim, Yongin-si (KR); Soon-Kwon Lim, Yongin-si (KR); Hong-Sick Park, Suwon-si (KR); Shi-Yul Kim, Yongin-si (KR); Eun-Guk Lee, Yongin-si (KR); Yang-Ho Bae, Suwon-si (KR); Byeong-Jin Lee, Yongin-si (KR); Jong-Hyun Choung, Suwon-si (KR); Sun-Young Hong, Seoul (KR); Bong-Kyun Kim, Incheon-si (KR); Won-Suk Shin, Yongin-si (KR); Sung-Wook Kang, Seoul (KR)

Correspondence Address: MACPHERSON KWOK CHEN & HEID LLP, 2033 GATEWAY PLACE, SUITE 400, SAN JOSE, CA, 95110, US

(21) Appl. No.: 11/544,738

(22) Filed: Oct. 5, 2006

(30) Foreign Application Priority Data
Oct. 5, 2005 (KR) 10-2005-0093539
Sep. 5, 2006 (KR) 10-2006-0085212

(51) Int. Cl. H01L 21/84; H01L 21/00; H01L 27/12; H01L 27/01; H01L 31/0392

(52) U.S. Cl. 438/149; 438/151; 257/347

(57) ABSTRACT

A thin film transistor array panel includes a pixel electrode formed on a substrate, a gate line formed on the pixel electrode, a gate insulating film formed on the gate line, a semiconductor formed on the gate insulating film, a data line and a drain electrode formed on the gate insulating film, and a passivation layer formed on portions of the data line and the drain electrode. The gate line includes a first film formed on the same layer and with the same material as the pixel electrode and a second film formed on the first film.

### CROSS-REFERENCE TO RELATED APPLICATION

This application claims priority to and the benefit of Korean Patent Applications No. 10-2005-0093539 and 10-2006-0085212 filed in the Korean Intellectual Property Office on Oct. 5, 2005 and Sep. 5, 2006, respectively, the contents of which are incorporated herein by reference.

### FIELD OF THE INVENTION

The present invention relates to thin film transistor panels and a method for manufacturing the same.

### DESCRIPTION OF THE RELATED ART

Active matrix display devices such as the liquid crystal display (LCD) and the organic light emitting display (OLED) include a plurality of pixels arranged in a matrix. A thin film transistor array panel includes a switching element such as a thin film transistor (TFT) and a plurality of signal lines such as gate lines and data lines to transmit signals to the TFTs. The TFT array panel is a multiple layered structure, including thin conductive films and insulating layers.

Conventionally, photolithography and etching steps are repeatedly used to pattern multiple thin film layers to form the TFT array panel. The photolithography steps increase manufacturing cost and time.

### SUMMARY OF THE INVENTION

In accordance with the invention, certain photolithography steps are eliminated by providing different thicknesses of photoresist from a single light exposure through a mask having different degrees of light transmission. The different thicknesses of photoresist enable selective etching of layers of materials underlying the photoresist. For example, a plurality of gate lines including gate electrodes and a plurality of pixel electrodes and a plurality of transparent conductors are obtained by selective application of etchants to layers of material formed on a substrate using portions of the photoresist as an etch mask that remain after removing other portions thereof.

According to an embodiment of the present invention, a thin film transistor (TFT) array panel includes a pixel electrode formed on a substrate, a gate line formed on the substrate, a gate insulating film formed on the gate line, a semiconductor formed on the gate insulating film, a data line and a drain electrode formed on the gate insulating film, and a passivation layer formed on portions of the data line and the drain electrode, wherein the gate line comprises a first film formed on the same layer and with the same material as the pixel electrode and a second film formed on the first film.

The second film of the gate line may include a first layer made of Mo (alloy), a second layer formed on the first layer and made of Al (alloy), and a third layer formed on the second layer and made of Mo (alloy). The TFT array panel may further include an insulating pattern including a column spacer formed on the passivation layer. The passivation layer may have a planar shape that is substantially the same as that of the insulating pattern.

According to the present invention, a thin film transistor array panel is made by forming a transparent conductive layer on a substrate, forming a conductive layer on the transparent conductive layer, forming a first photoresist on the conductive layer, etching the conductive layer with a first etchant using the first photoresist as a mask, etching the transparent conductive layer with a second etchant that is different from the first etchant using the first photoresist as a mask to form a gate line, applying a second photoresist, removing the exposed conductive layer with the first etchant using the second photoresist as a mask to form a pixel electrode, forming a gate insulating film on the gate line and the pixel electrode, forming a semiconductor on the gate insulating film, forming a data line and a drain electrode on the semiconductor, forming a first insulating layer and a second insulating layer on the data line and the drain electrode, exposing the second insulating layer to light to form an insulating pattern including a spacer, and etching the first insulating layer using the insulating pattern as a mask to form a passivation layer. The first photoresist may be formed by a photo mask including a light blocking area, a translucent area, and a light transmitting area.

The semiconductor may include a first semiconductor layer and a second semiconductor layer and a second semiconductor layer. The formation of the gate insulating film, the formation of the semiconductor, and the formation of the data line and the drain electrode may include depositing a gate insulating layer, an intrinsic a-Si layer, and an extrinsic a-Si layer on the pixel electrodes, applying a third photoresist on the extrinsic a-Si layer, sequentially etching the extrinsic a-Si layer, the intrinsic a-Si layer, and the gate insulating layer to form the gate insulating film, changing the third photoresist to form a fourth photoresist, etching the extrinsic a-Si layer and the intrinsic a-Si layer using the fourth photoresist as a mask to form the first semiconductor layer, forming a data conductive layer on the exposed pixel electrodes, the exposed gate insulating film, and the exposed extrinsic a-Si layer, applying a fifth photoresist on the data conductive layer, removing the exposed data conductive layer using the fifth photoresist as a mask to form the data line and the electrode line, and etching the exposed extrinsic a-Si layer using the fifth photoresist as a mask to form the second semiconductor layer.

### BRIEF DESCRIPTION OF THE DRAWINGS

The foregoing and other objects features and advantages of the present invention will become more apparent from a reading of the ensuing description together with the drawing, in which:

FIG. 1 is a layout view of a TFT array lower panel according to an exemplary embodiment of the present invention.

FIGS. 2A and 2B are sectional views of the TFT array panel shown in FIG. 1 taken along the lines IIA-IIA and IIB-IIB, respectively.

FIGS. 3A and 3B are sectional views of the TFT array panel shown in FIG. 1 taken along the lines IIA-IIA and IIV-IIB, in the first step of a manufacturing method of the TFT array panel according to an exemplary embodiment of the present invention, respectively.

FIGS. 4A and 4B illustrate the step following the step shown in FIGS. 3A and 3B, respectively.

FIGS. 5A and 5B illustrate the step following the step shown in FIGS. 4A and 4B, respectively.

FIGS. 6A and 61B illustrate the step following the step shown in FIGS. 5A and 51B, respectively.

FIGS. 7, 12, and 17 are layout views of the TFT array panel shown in FIGS. 1-2B in intermediate steps of a manufacturing method thereof according to an exemplary embodiment of the present invention.

FIGS. 8A and 81B are sectional views of the TFT array panel shown in FIG. 7 taken along the lines VIIIA-VIIIA and VIIIB-VIIIB, respectively.

FIGS. 9A and 91B are sectional views of the TFT array panel shown in FIG. 7 taken along the lines VIIIA-VIIIA and VIIIB-VIIIB, in the step following the step shown in FIGS. 8A and 81B, respectively.

FIGS. 10A and 10B illustrate the step following the step shown in FIGS. 9A and 91B, respectively.

FIGS. 11A and 11B illustrate the step following the step shown in FIGS. 10A and 10B, respectively. FIGS. 13A and 13B are sectional views of the TFT array panel shown in FIG. 12 taken along the lines XIIIA-XIIIA and XIIIB-XIIIB, respectively.

FIGS. 14A and 141B are sectional views of the TFT array panel shown in FIG. 12 taken along the lines XIIIA-XIIIA and XIIIB-XVIIIB, in the step following the step shown in FIGS. 13A and 13B, respectively.

FIGS. 15A and 151B illustrate the step following the step shown in FIGS. 14A and 14B, respectively.

FIGS. 16A and 161B illustrate the step following the step shown in FIGS. 15A and 15B, respectively.

FIGS. 18A and 181B are sectional views of the TFT array panel shown in FIG. 17 taken along the lines XVIIIA-XVIIIA and XVIIIB-XVIIIB, respectively.

FIGS. 19A and 19B illustrate the step following the step shown in FIGS. 18A and 18B, respectively.

FIGS. 20A and 20B illustrate the step following the step shown in FIGS. 19A and 19B, respectively.

FIG. 21 is a layout view of a TFT array panel according to another exemplary embodiment of the present invention.

FIGS. 22A and 22B are sectional views of the TFT array panel shown in FIG. 21 taken along the lines XXIIA-XXIIA and XXIIB-XXIIB, respectively.

FIGS. 23A and 23B are sectional views of the TFT array panel shown in FIG. 21 taken along the lines XXIIA-XXIIA and XXIIV-XXIIB, in the first step of a manufacturing method of the TFT array panel according to another exemplary embodiment of the present invention, respectively.

FIGS. 24A and 24B illustrate the step following the step shown in FIGS. 23A and 23B, respectively.

FIGS. 25A and 25B illustrate the step following the step shown in FIGS. 24A and 24B, respectively.

FIGS. 26, 31, and 37 are layout views of the TFT array panel shown in FIGS. 21-22B in intermediate steps of a manufacturing method thereof according to another exemplary embodiment of the present invention.

FIGS. 27A and 27B are sectional views of the TFT array panel shown in FIG. 26 taken along the lines XXVIIA-XXVIIA and XXVIIB-XXVIIB, respectively.

FIGS. 28A and 28B are sectional views of the TFT array panel shown in FIG. 26 taken along the lines XXVIIA-XXVIIA and XXVIIB-XXVIIB, in the step following the step shown in FIGS. 27A and 27B, respectively.

FIGS. 29A and 29B illustrate the step following the step shown in FIGS. 28A and 28B, respectively.

FIGS. 32A and 32B are sectional views of the TFT array panel shown in FIG. 31 taken along the lines XXXIIA-XXXIIA and XXXIIB-XXXIIB, respectively.

FIGS. 33A and 33B are sectional views of the TFT array panel shown in FIG. 31 taken along the lines XXXIIA-XXXIIA and XXXIIB-XXXIIB, in the step following the step shown in FIGS. 32A and 32B, respectively.

FIGS. 34A and 34B illustrate the step following the step shown in FIGS. 33A and 33B, respectively.

FIGS. 35A and 35B illustrate the step following the step shown in FIGS. 34A and 34B, respectively.

FIGS. 36A and 36B illustrate the step following the step shown in FIGS. 35A and 35B, respectively.

FIGS. 38A and 38B are sectional views of the TFT array panel shown in FIG. 37 taken along the lines XXXVIIIA-XXXVIIIA and XXXVIIIB-XXXVIIIB, respectively.

FIGS. 39A and 39B are sectional views of the TFT array panel shown in FIG. 37 taken along the lines XXXVIIIA-XXXVIIIA and XXXVIIIB-XXXVIIIB, in the step following the step shown in FIGS. 38A and 38B, respectively.

FIGS. 40A and 40B illustrate the step following the step shown in FIGS. 39A and 39B, respectively.

FIG. 41 is a layout view of a TFT array panel according to further another exemplary embodiment of the present invention.

FIGS. 42A and 42B are sectional views of the TFT array panel shown in FIG. 41 taken along the lines XLIIA-XLIIA and XLIIB-XLIIB, respectively.

FIGS. 43A and 43B illustrate the step following the step shown in FIGS. 15A and 15B, respectively.

FIGS. 44A and 44B illustrate the step following the step shown in FIGS. 43A and 43B, respectively.

FIG. 45 is a layout view of a TFT array panel according to further more another exemplary embodiment of the present invention.

FIGS. 46A and 46B are sectional views of the TFT array panel shown in FIG. 45 taken along the lines XLVIA-XLVIA and XLVIB-XLVIB, respectively.

FIGS. 47A and 47B illustrate the step following the step shown in FIGS. 34A and 34B, respectively.

FIGS. 48A and 48B illustrate the step following the step shown in FIGS. 47A and 47B, respectively.

### DETAILED DESCRIPTION OF THE EMBODIMENTS

In the drawings, the thickness of layers and regions are exaggerated for clarity. It will be understood that when an element such as a layer, region, or substrate is referred to as being “on” another element, it can be directly on the other element or intervening elements may also be present. In contrast, when an element is referred to as being “directly on” another element, there are no intervening elements present.

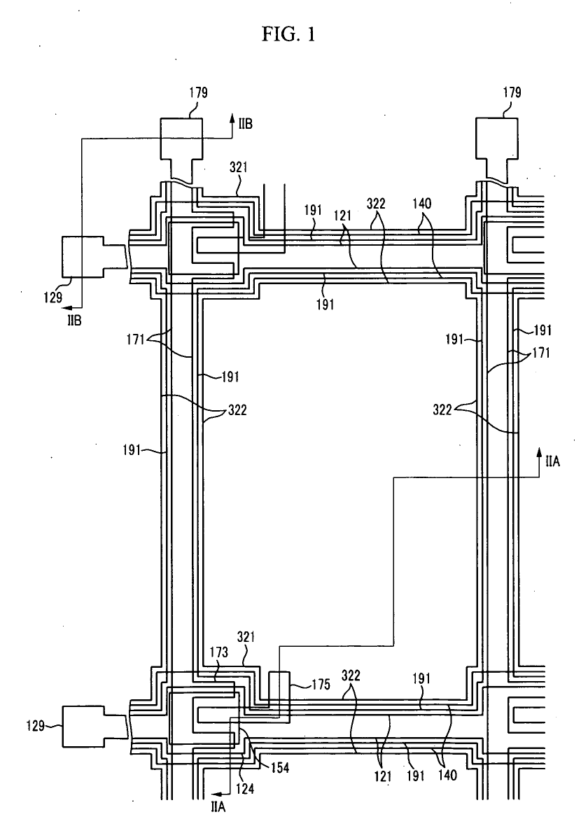

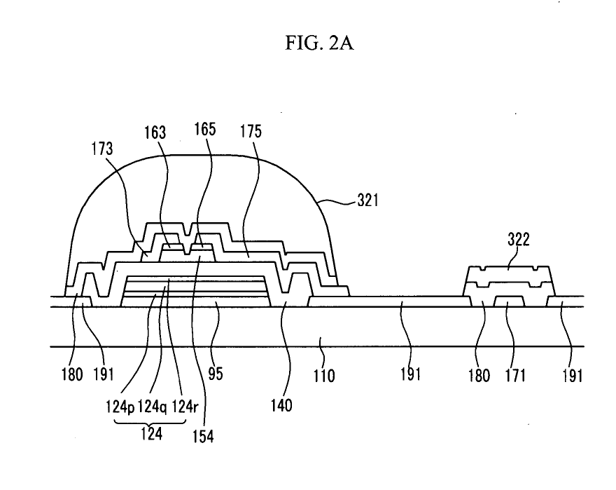

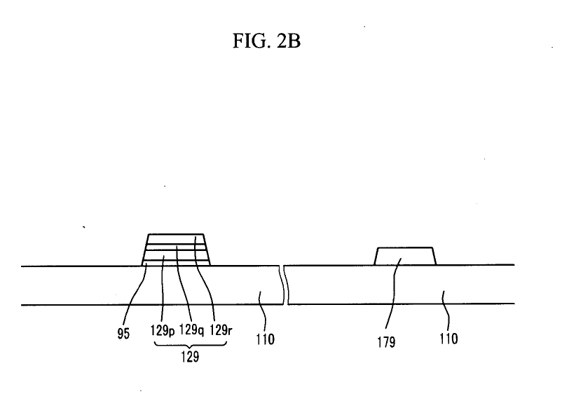

FIG. 1 is a layout view of a TFT array lower panel according to an embodiment of the present invention, FIG. 2A is a sectional view of the TFT array panel shown in FIG. 1 taken along the line IIA-IIA, and FIG. 2B is a sectional view of the TFT array panel shown in FIG. 1 taken along the lines IIB-IIB.

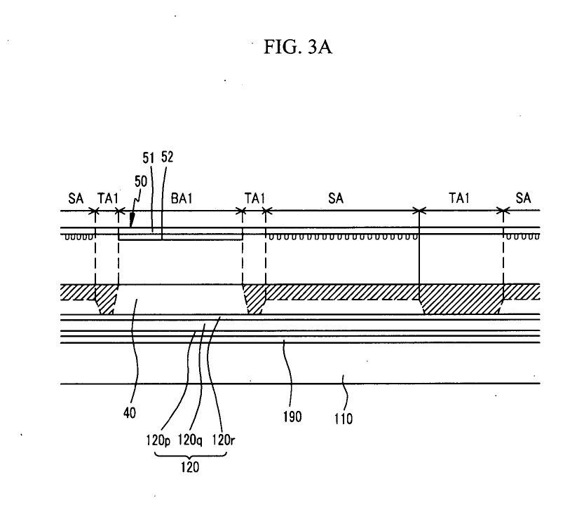

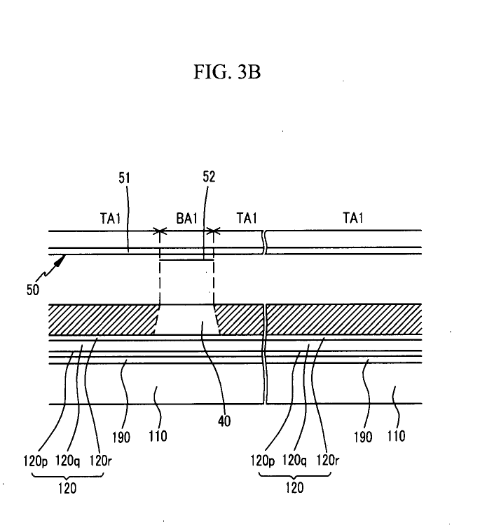

Referring to FIGS. 1 to 2B, a plurality of pixel electrodes 191 and a plurality of transparent conductors 95 are formed on an insulating substrate 110 that is made of a material such as transparent glass or plastic. The pixel electrodes 191 and the transparent conductors 95 are formed by selective etching of a layer 190 (FIG. 3A) made of transparent conductive material such as amorphous ITO (a-ITO), ITO or IZO. The etching process causes the lateral sides of pixel electrodes 191 and conductors 95 to be inclined relative to the surface of substrate 110 at an inclination angle that ranges from about 30 to 80 degrees.

A plurality of gate lines 121 (FIG. 1) are formed on insulating substrate 110. Gate lines 121 transmit gate signals and extend substantially in a transverse direction. Each of gate lines 121 includes a plurality of gate electrodes 124 projecting upward and downward and end portions 129 having a large area for contact with another layer or an external driving circuit. A gate driving circuit (not shown) for generating the gate signals may be mounted on a flexible printed circuit (FPC) film (not shown), which may be attached to substrate 110, directly mounted on substrate 110, or integrated onto substrate 110. Gate lines 121 may extend to be connected to a driving circuit that may be integrated onto substrate 110.

Gate lines 121 have a triple-layered structure (as shown in FIG. 2A) which includes a lower film, an intermediate film, and an upper film. The lower film is preferably made of a refractory metal such as Cr, Mo, Ta, Ti, or alloys thereof, the intermediate film is preferably made of a low resistivity metal such as an Al-containing metal, an Ag-containing metal, and a Cu-containing metal, and the upper film is made of a refractory metal or alloys thereof having good contact characteristics with a-ITO. A good example of the combination of the three films is a lower Mo (alloy) film, an intermediate Al (alloy) film, and an upper Mo (alloy) film.

Gate lines 121 may have a double-layered structure including a refractory-metal lower film (not shown) and a low-resistivity upper film (not shown) or a single-layer structure preferably made of the above-described materials. A good example of the combination of the two films is a lower Cr/Mo (alloy) film and an upper Al (alloy) film. However, gate lines 121 may be made of various metals or conductors. The lateral sides of gate lines 121 are inclined relative to the surface of substrate 110, the inclination angle thereof ranging from about 30 to 80 degrees. Conductors 95 are formed only under of gate lines 121.

A plurality of gate insulating films 140 preferably made of silicon nitride (SiNx) or silicon oxide (SiOx) are formed on gate lines 121 except for end portions 129 thereof. Gate insulating films 140 overlap edge portions of pixel electrodes 191 to enlarge the aperture ratio of the pixels.

A plurality of semiconductor islands 154, preferably made of hydrogenated amorphous silicon (abbreviated to “a-Si”) or polysilicon, are formed on gate insulating films 140. Semiconductor islands 154 are disposed on the gate electrodes 124.

A plurality of ohmic contact islands 163 and 165 (FIG. 2A) are formed on semiconductor islands 154. Ohmic contact islands 163 and 165 are preferably made of n+ hydrogenated a-Si heavily doped with an N-type impurity such as phosphorous, or they may be made of silicide. Ohmic contact islands 163 and 165 are located in pairs on projections of semiconductor islands 154. The lateral sides of semiconductor islands 154 and the ohmic contacts 163 and 165 are inclined relative to the surface of substrate 110, and the inclination angles thereof are preferably in a range of about 30 to 80 degrees.

A plurality of data lines 171 (FIG. 1) and a plurality of drain electrodes 175 are formed on ohmic contact islands 163 and 165, gate insulating films 140, and portions of pixel electrodes 191.

Data lines 171 transmit data signals and extend substantially in the longitudinal direction to intersect gate lines 121. Each data line 171 includes a plurality of source electrodes 173 projecting toward the gate electrodes 124 and an end portion 179 having a large area for contact with another layer or an external driving circuit. A data driving circuit (not shown) for generating the data signals may be mounted on an FPC film (not shown), which may be attached to substrate 110, directly mounted on substrate 110, or integrated onto substrate 110. Data lines 171 may extend to be connected to a driving circuit that may be integrated onto substrate 110.

Drain electrodes 175 are separated from data lines 171 and disposed opposite source electrodes 173 with respect to the gate electrodes 124. Each of drain electrodes 175 has a bar shape. One portion of drain electrode 175 overlaps pixel electrode 191 and another portion is partly enclosed by source electrode 173 curved like the character “C.”

A gate electrode 124, a source electrode 173, and a drain electrode 175 along with a semiconductor island 154 form a TFT having a channel formed in the semiconductor island 154 disposed between the source electrode and the drain electrode.

Data lines 171 and drain electrodes 175 are preferably made of a refractory metal such as Cr, Mo, Ta, Ti, or alloys thereof. However, they may have a multilayered structure including a refractory metal film (not shown) and a low resistivity film (not shown). Good examples of the multi-layered structure are a double-layered structure including a lower Cr/Mo (alloy) film and an upper Al (alloy) film, and a triple-layered structure of a lower Mo (alloy) film, an intermediate Al (alloy) film, and an upper Mo (alloy) film. However, data lines 171 and drain electrodes 175 may be made of various metals or conductors.

Data lines 171 and drain electrodes 175 have inclined edge profiles, and the inclination angles thereof range from about 30 to 80 degrees.

Ohmic contacts 163 and 165 are interposed only between the underlying semiconductor islands 154 and the overlying conductors 171 and 175 thereon, and they reduce the contact resistance therebetween. The ohmic contacts include portions projected along with the underlying semiconductors 154 between source electrodes 173 and drain electrodes 175.

Pixel electrodes 191 are physically and electrically connected to drain electrodes 175 such that pixel electrodes 191 receive data voltages from drain electrodes 175. Pixel electrodes 191 supplied with the data voltages generate electric fields in cooperation with a common electrode (not shown) of the opposing display panel supplied with a common voltage, which determine the orientations of the liquid crystal molecules (not shown) in the liquid crystal layer (not shown) disposed between the two panels. Thereby, the polarization of light passing through the liquid crystal layer is varied by the orientations of the liquid crystal molecules. A pixel electrode 191 and a common electrode form a capacitor referred to as “liquid crystal capacitor,” which stores applied voltages after the TFT turns off. An additional capacitor, which is connected in parallel to the liquid crystal capacitor, may be provided for enhancing the voltage storing capacity.

Semiconductor islands 154 include some exposed portions, which are not covered with source electrodes 173 and drain electrodes 175, such as portions located between source electrodes 173 and drain electrodes 175.

A passivation layer 180 is formed on data lines 171, drain electrodes 175, and the exposed portions of semiconductor islands 154 and gate insulating films 140.

Passivation layer 180 covers gate lines 121 that extend substantially in the transverse direction and data lines 171 that extend substantially in the longitudinal direction.

Passivation layer 180 includes expansions projecting downward and upward near portions under which source electrodes 173 and drain electrodes 175 are substantially formed, and overlaps edge portions of the adjacent pixel electrodes 191. However, passivation layer 180 may have almost the same boundary lines as the adjacent pixel electrodes 191 but may or may not overlap the adjacent pixel electrodes 191.

Passivation layer 180 is made of an inorganic insulator such as silicon nitride and silicon oxide, and may have a flat top surface. However, passivation layer 180 may be made of an organic insulator having photosensitivity and a dielectric constant lower than 4.0. Passivation layer 180 may have a double-layered structure including a lower inorganic film and an upper organic film, to have a good insulating characteristic of the organic film and to protect the exposed semiconductor islands 154.

An insulating pattern 322 is formed on passivation layer 180. The insulating pattern 322 includes a plurality of spacers 321. The spacers 321 may be column spacers. The insulating pattern 322 has almost the same planar shape as passivation layer 180 and substantially extends along gate lines 121 and data lines 171.

Spacers 321 are only formed on portions at which light does not pass, such as portions near the TFTs, and are projected from the insulating pattern 322 by a predetermine thickness. Alternatively, spacers 321 may be formed on positions corresponding to portions of gate lines 121 and portions of data lines 171.

Now, a method of manufacturing the TFT array panel shown in FIGS. 1-2B will be described in detail with reference to FIGS. 3-20B as well as FIGS. 1-2B. Referring to FIGS. 3A and 3B, a-ITO is deposited by sputtering, etc., on an insulating substrate 110 preferably made of transparent glass, to form a transparent conductive layer 190.

Then, a conductive layer 120 including a lower Mo film 120p, an intermediate Al film 120q, and an upper Mo 120r is deposited by performing a sputtering process, etc., and a photoresist 40 with a thickness of about 1-2 microns is coated on conductive layer 120. Photoresist 40 is exposed to light through a photo mask 50, and developed.

Photo mask 50 includes a transparent substrate 51 and an opaque light blocking film 52 on the transparent substrate 51, and is divided into light transmitting areas TA1, light blocking areas BA1, and translucent areas SA. The light blocking film 52 has openings disposed on the light transmitting areas TA1 and slits disposed on the translucent areas SA, based on widths thereof. That is, the openings have widths greater than a predetermined value, and the slits have widths less than the predetermined value.

The position-dependent thickness of photoresist 40 may be obtained by several techniques, which include, for example, providing translucent areas on the exposure mask 50 as well as by providing light transmitting areas and light blocking opaque areas. The 20 translucent areas may have a slit pattern, a lattice pattern, or have a thin film or films with intermediate transmittances or thickness. When using a slit pattern, it is preferable that the width of the slits or the distance between the slits is smaller than the resolution of a light exposer used for the photolithography. Alternatively, a reflowable photoresist may be used. For example, a photoresist pattern made of a reflowable material is formed using a normal exposure mask that has only transparent areas and opaque areas. The mask is then subjected to a reflow process allowing the reflowable material to flow onto areas lacking the photoresist, thereby forming thin portions of photoresist.

After being exposed to light through photo mask 50 and developed, photoresist 40 has a position-dependent thickness. The different thicknesses of photoresist 40 enables selective etching of the underlying layers when using suitable process conditions.

Therefore, a plurality of gate lines 121 including gate electrodes 124 and a plurality of pixel electrodes 191 and a plurality of transparent conductors 95 are obtained by a series of etching steps. The formation of gate lines 121 and pixel electrodes 191 and the transparent conductors 95 will be described in detail.

As shown in FIGS. 3A and 3B, the translucent areas SA face pixel electrodes 191, the light blocking areas BA1 face gate lines 121, and the light transmitting areas TA1 face the remaining areas. Photoresist 40 is exposed to light through the photo mask 50 and is developed such that portions of photoresist 40 that have received a predetermined amount of light are removed.

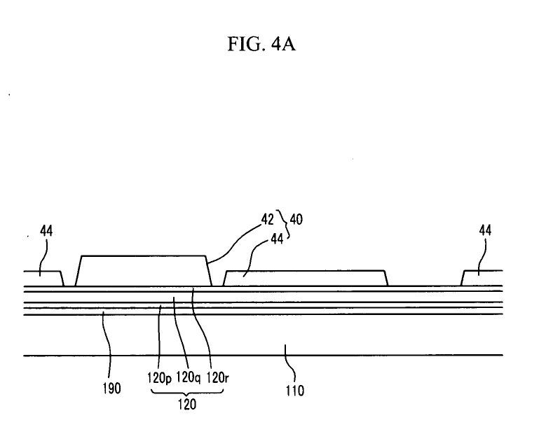

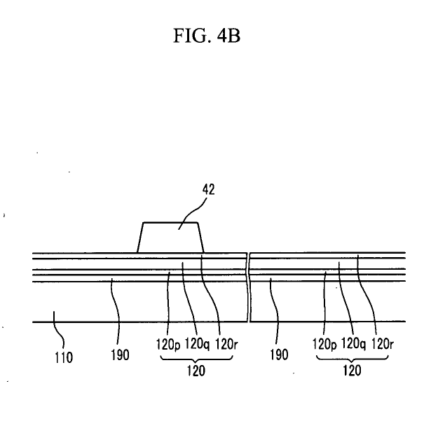

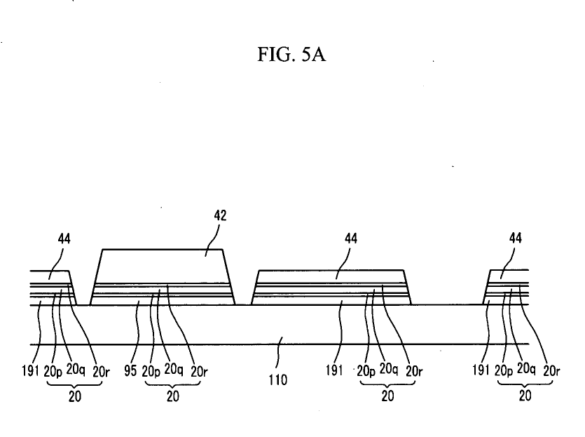

Referring to FIGS. 4A and 4B, portions of photoresist 40 facing the light transmitting areas TA1 are removed, portions 44 of photoresist 40 facing the translucent areas SA come to have a reduced thickness, and portions 42 of photoresist 40 facing the light blocking areas BA1 are left intact. In FIGS. 3A and 3B, the hatched portions indicate the portions of photoresist 40 that have been removed after development.

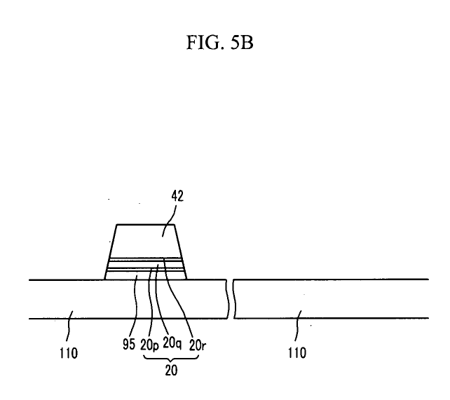

Referring to FIGS. 5A and 5B, the exposed conductive layer 120 is etched using the remaining portions 42 and 44 of photoresist 40 as an etch mask. At this time, the etchant for the etching includes phosphoric acid, nitric acid, acetic acid, and an additive in an appropriate ratio. Preferably, an integrated etchant that includes about 60 to 75% phosphoric acid, about 2 to 8% nitric acid, about 5 to 15% acetic acid, and about 0.5 to 3% additive may be used.

The integrated etchant has a good profile in etching and does not influence the underlying conductive layer 190, to prevent bad patterns due to undesired etching of the transparent conductive layer 190.

The exposed transparent conductive layer 190 is etched again using the remaining portions 42 and 44 of photoresist 40 as an etch mask, to form pixel electrodes 191 and the transparent conductor 95. At this time, portions of the etched pixel electrodes 191 and portions of the transparent conductors 95 may be cut under the overlying etched conductive layers 20, such that undercuts may be formed. The etchant includes sulfuric acid and nitric acid in an appropriate ratio. Preferably, a pixel integrated etchant that includes about 2 to 15% sulfuric acid and about 0.02 to 10% nitric acid may be used.

In an embodiment of the present invention, the conductive layer 120 and the transparent conductive layer 190 are etched using different etchants such as the integrated etchant and the pixel integrated etchant, respectively, but the conductive layer 120 and the transparent conductive layer 190 may be simultaneously etched using the same etchant. In this case, the manufacturing processes become simpler and the manufacturing cost is reduced.

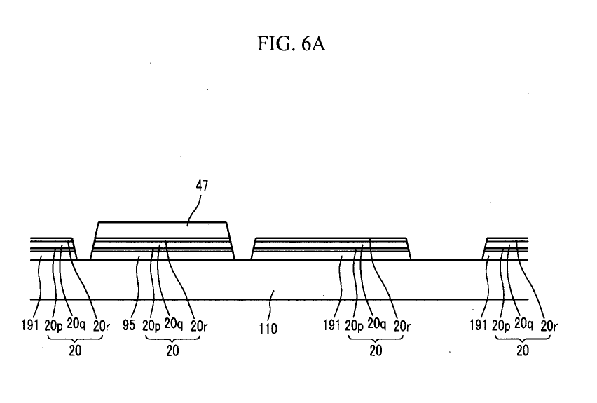

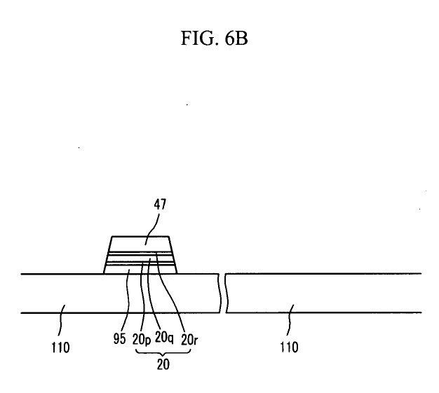

Next, portions 44 of photoresist 40 (FIG. 5A) are removed and, as shown in FIGS. 6A and 6B, the remaining portions 42 have reduced thicknesses to form portions 47, by performing an ashing process, etc. Thereby, the upper films 20r of conductive layers 20 are exposed.

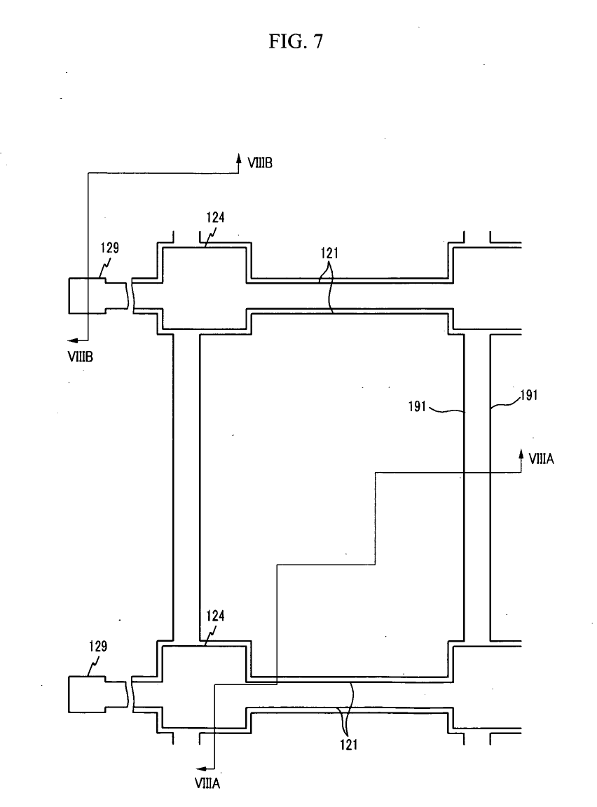

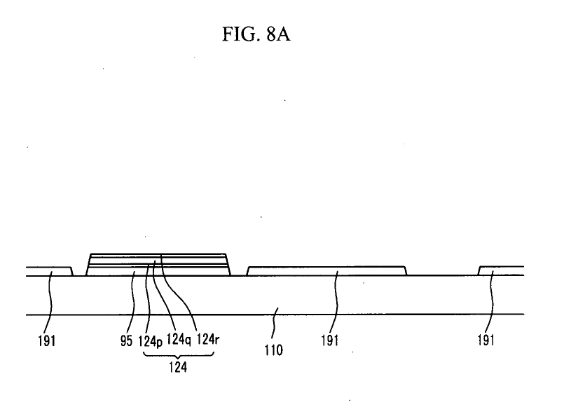

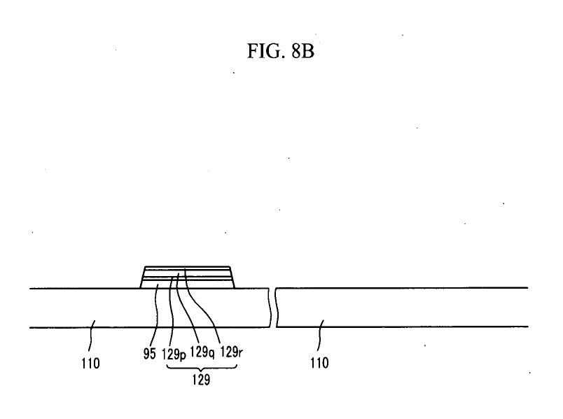

Referring to FIGS. 7 to 8B, the exposed conductive layers 20 are etched using the remaining portions 47 of photoresist 40 as an etch mask, to form gate lines 121 including the gate electrodes 124. The etchant includes phosphoric acid, nitric acid, acetic acid, and an additive in an appropriate ratio, and preferably the integrated etchant may be used. At this time, since exposed lateral portions of the conductive layers 20 are etched, that is, the side etching is performed, the undercuts formed under the conductive layers 20 are removed.

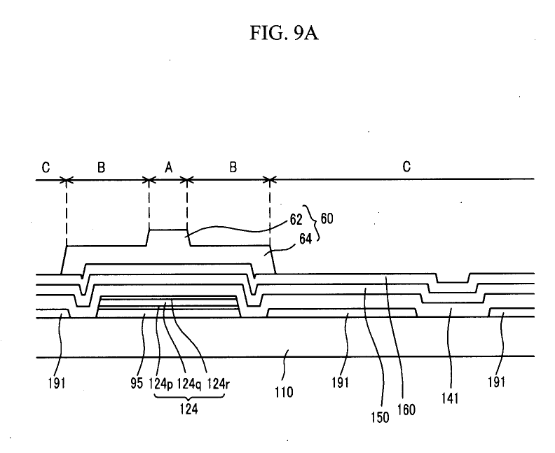

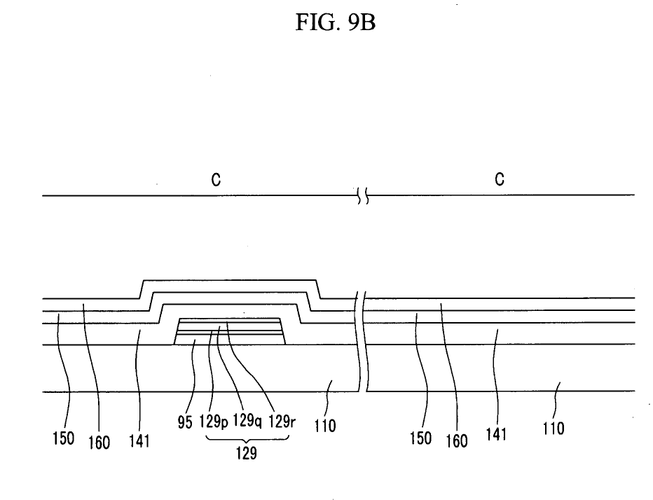

As shown in FIGS. 9A and 9B, a gate insulating layer 141, an intrinsic a-Si layer 150, and an extrinsic a-Si layer 160 are sequentially deposited by CVD, and a photoresist 60 with a thickness of about 1 to 2 microns is coated on the extrinsic a-Si layer 160. The gate insulating layer 141 may be made of a material such as silicon nitride (SiNx) and it is preferable that the CVD is performed under a low temperature such as about 240 to 280° C. for preventing damage to the underlying pixel electrodes 191. The gate insulating layer 141 may have a thickness of about 2000-5000 Å. Alternatively, the gate insulating layer 141 may be deposited using a deposition manner in which pixel electrodes 191 are not reduced. A-ITO used as a material of the transparent conductive layer 190 may be changed into poly-ITO by heat occurring in the forming of the gate insulating layer 141 to enhance transmittance, etc., of pixels.

Next, photoresist 60 is exposed by light through a photo mask (not shown) and developed such that the photoresist 60 has a position-dependent thickness. Photoresist 60 shown in FIGS. 9A and 9B includes a plurality of first to third portions in order of decreasing thickness. The first portions located on areas A and the second portions located on areas B are indicated by reference numerals 62 and 64, respectively. No reference numeral is assigned to the third portions located on remaining areas C since they have substantially zero thickness so that underlying portions of the extrinsic a-Si layer 160 can be exposed. The thickness ratio of the first portions 62 and the second portions 64 is adjusted depending upon the conditions in subsequent process steps. It is preferable that the thickness of the second portions 64 is equal to or less than half the thickness of the first portions 62, and in particular, equal to or less than 4000 Å.

The position-dependent thickness of the photoresist may be obtained by several techniques, which include, for example, providing translucent areas on the exposure mask 50 as well as by providing light transmitting areas and light blocking opaque areas on the exposure mask. The translucent areas may have a slit pattern, a lattice pattern, or have a thin film or films with intermediate transmittances or thickness. When using a slit pattern, it is preferable that the width of the slits or the distance between the slits is smaller than the resolution of a light exposer used for the photolithography. As another example, a reflowable photoresist may be used. For example, when a photoresist pattern made of a reflowable material is formed by using a normal exposure mask with only transparent areas and opaque areas, it is subject to a reflow process whereby the reflowable material flows onto areas not including the photoresist, thereby forming thin portions of photoresist.

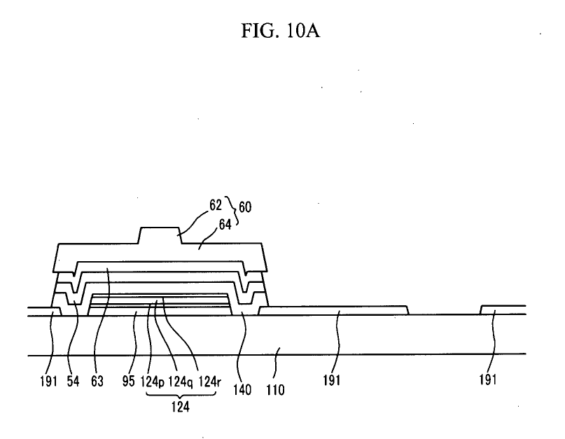

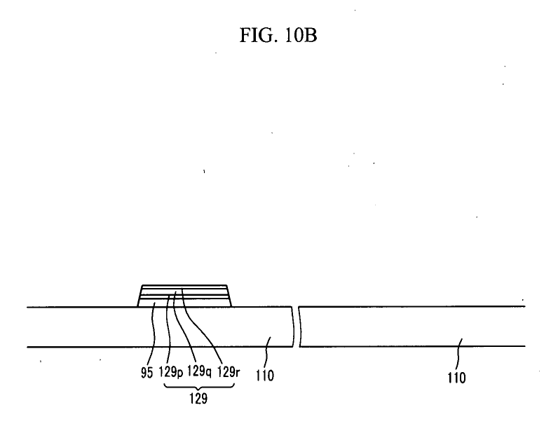

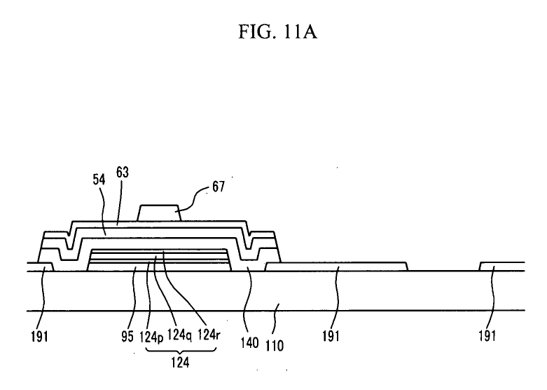

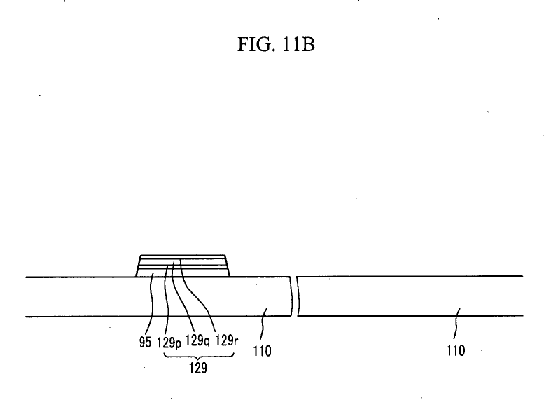

Referring to FIGS. 10A and 10B, the exposed a-Si layers 160 and 150 and the exposed gate insulating layers 141 are sequentially etched using the remaining portions 62 and 64 as an etch mask to form a plurality of a-Si islands 63 and 54 and a plurality of gate films 140, and then the second portions 64 of the photoresist 60 is then removed and the first portions 62 of the photoresist 60 have reduced thicknesses to form portions 67 of the photoresist 60, as shown in FIGS. 11A and 11B.

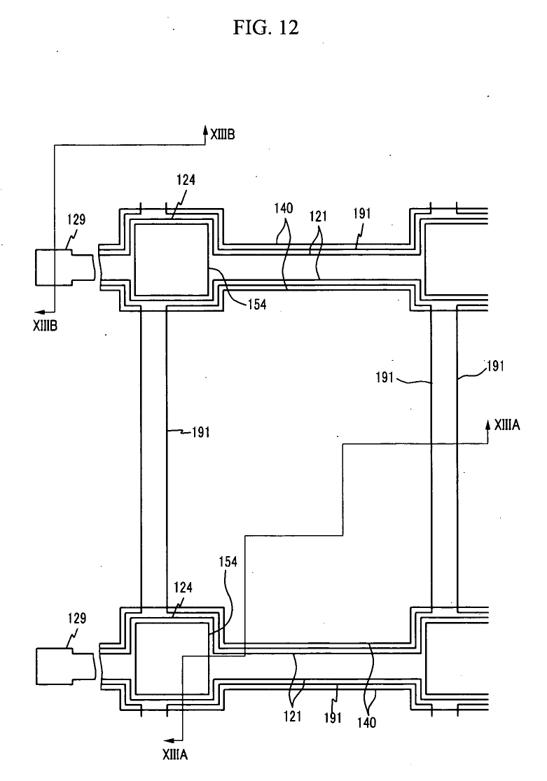

Referring to FIGS. 12 to 13B, the exposed a-Si islands 63 and 54 are sequentially etched using the portions 67 of the photoresist 60 as an etch mask, to form a plurality of extrinsic a-Si islands 63 and a plurality of semiconductor islands 154

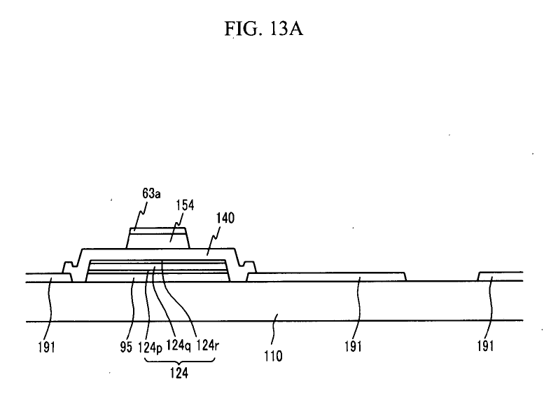

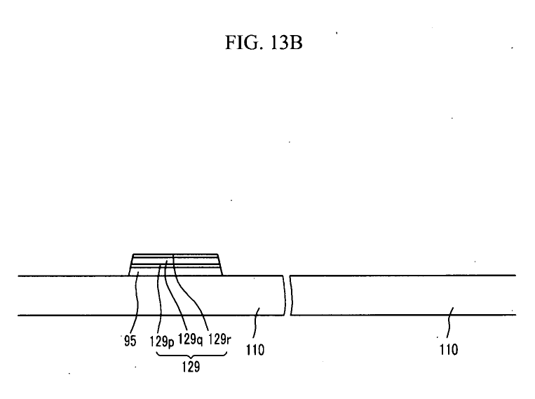

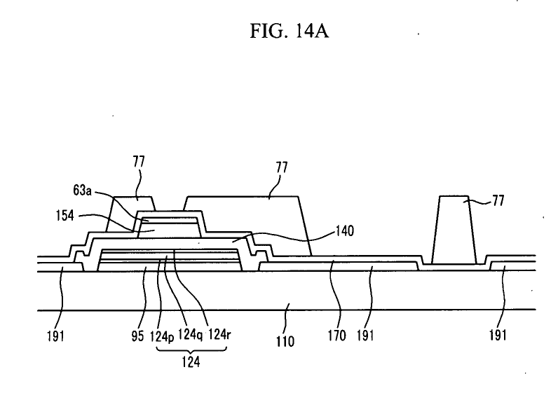

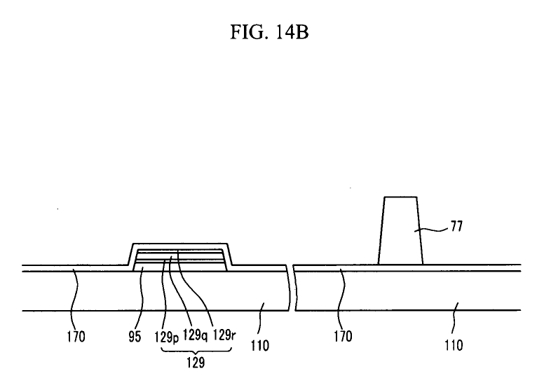

Referring to FIGS. 14A and 14B, a conductive layer 170 made of a material such as a metal, etc., is deposited with a predetermined thickness by performing a sputtering process. A photoresist (not shown) coated on conductive layer 170 is exposed to light through a photo mask (not shown) and is developed.

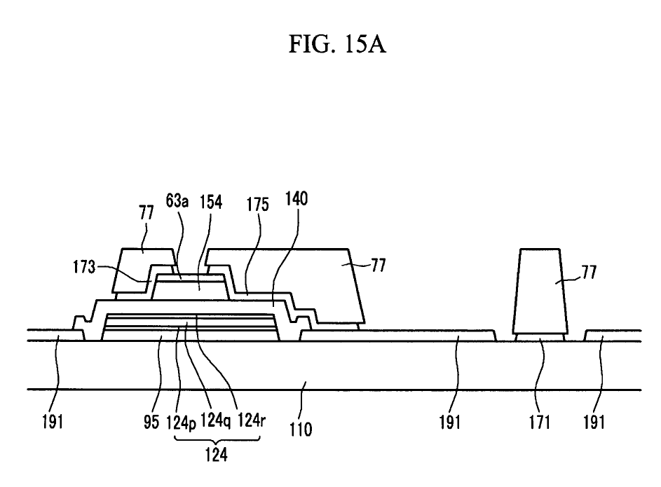

Referring to FIGS. 15A and 15B, the exposed conductive layer 170 is etched using photoresist portions 77 as an etching mask to form a plurality of data lines including source electrodes 173 and a plurality of drain electrodes 175. At this time, undercuts occurs under the photoresist portions 77.

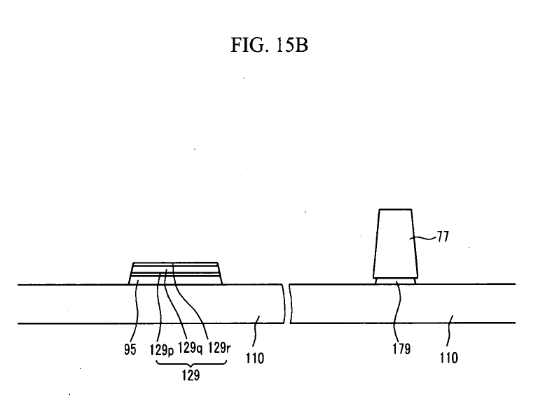

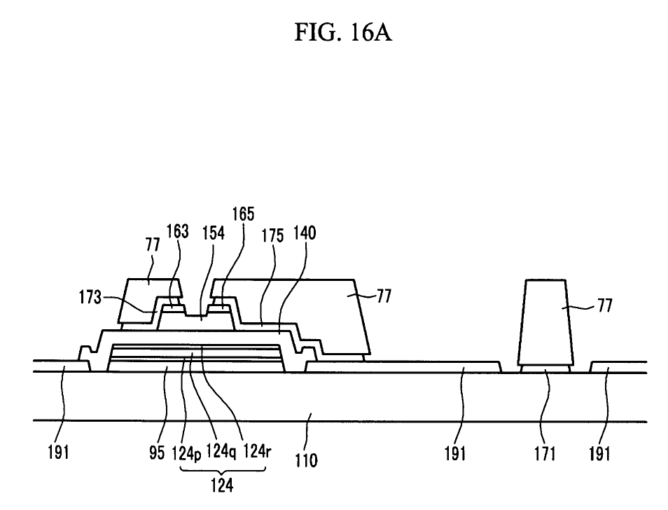

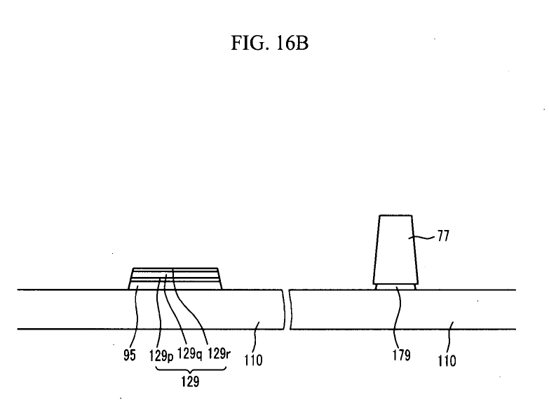

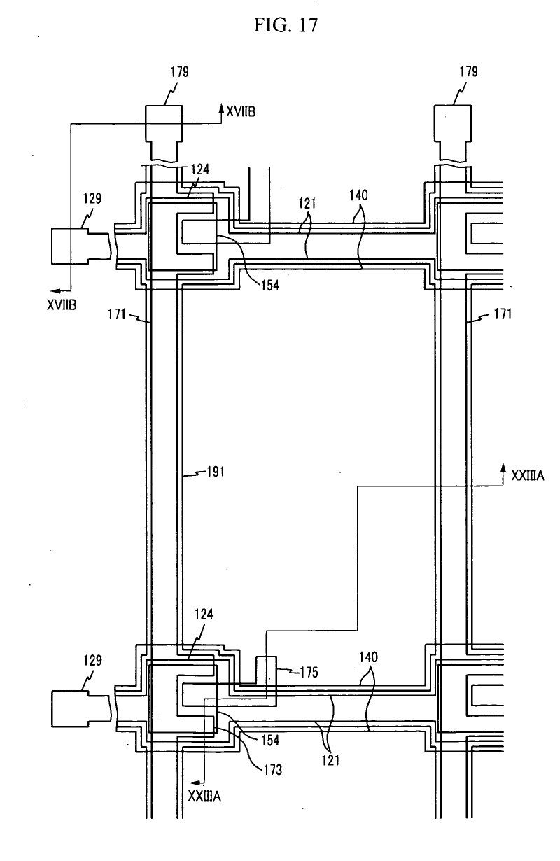

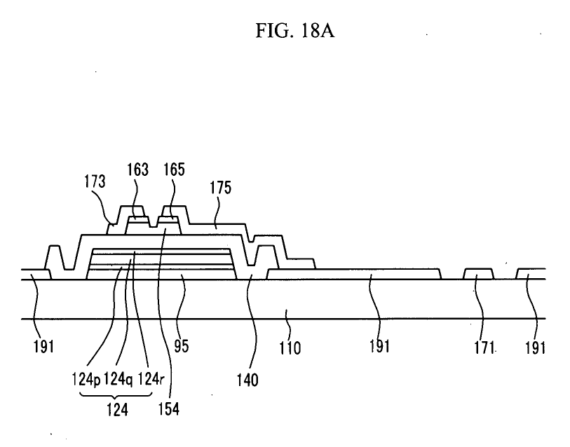

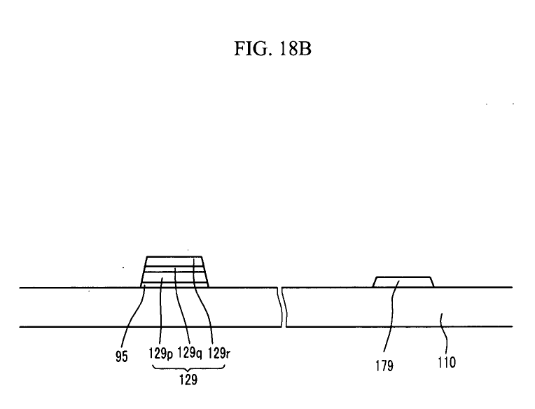

Referring to FIGS. 16A and 16B, the exposed extrinsic a-Siislands 63 not covered by source electrodes 173 and drain electrodes 175 are removed again using the photoresist portions 77 as an etching mask to form a plurality of ohmic contact islands 163 and 165, and then the photoresist portions 77 are removed (refer to FIGS. 17 to 18B). At this time, the portions of the semiconductors 154 under the exposed a-Si islands 63 are etched, but may be not etched. Portions of the contact assistants 163 and 165 are exposed along with the underlying semiconductors 154 between source electrodes 173 and drain electrodes 175 due to the undercuts under the photoresist portions 77.

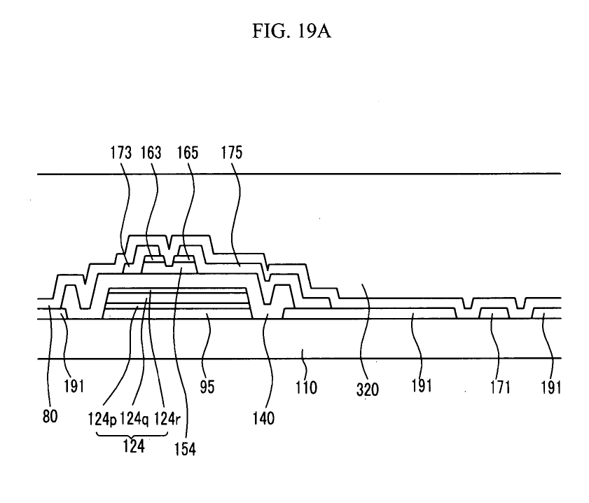

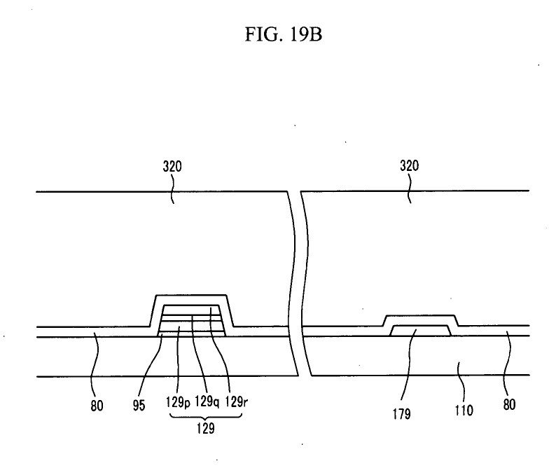

Referring to FIGS. 19A and 19B, a first insulating layer 80 and a second insulating layer 320 having photosensitivity are sequentially deposited.

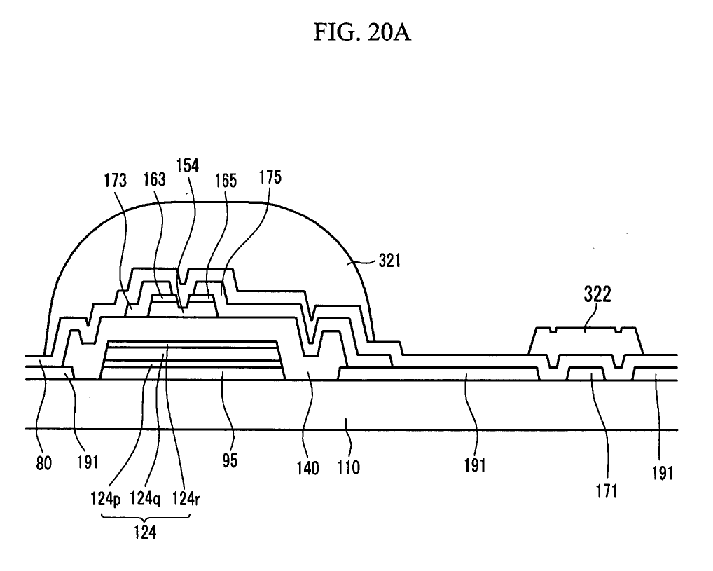

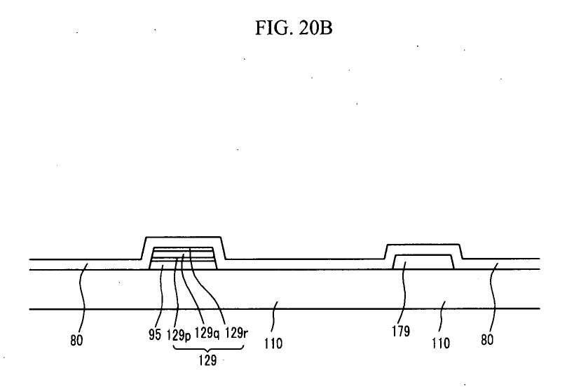

Referring to FIGS. 20A and 20B, the second insulating layer 320 is exposed to light through a slit mask (not shown) and developed such that an insulating pattern 322 including a plurality of column spacers 321 is formed.

The insulating pattern 322 has a position-dependent thickness. Thereby, a height of the insulating pattern 322 formed on transistor portions through which light is not passed is greater than a height of the insulating pattern 322 formed on the remaining portions, to form projections projecting upward. As a result, the projections function as the column spacers 321. The column spacers 321 may be formed on positions corresponding to portions of data lines 171 and portions of gate lines 121.

The exposed first insulating layer 80 is etched using the insulating pattern 322 including the column spacers 321 as an etch mask to form a passivation layer 180 (refer to FIGS. 1 to 2B). At this time, since the second insulating layer 320 is etched with a shape extending along gate lines 121 and data lines 171 to form the insulating pattern 322, passivation layer 180 also extends along gate lines 121 and data lines 171.

As described above, pixel electrodes 191 are formed along with gate lines 121 using one mask, and thereby the number of manufacturing processes decreases and the manufacturing cost is reduced.

In addition, in manufacturing the TFT array panel, the insulating pattern including the spacers is simultaneously formed and the passivation layer is formed using the insulating pattern without a mask, and thereby the number of manufacturing processes decreases and the manufacturing cost is reduced.

Furthermore, the pixel electrodes are formed under the passivation layer. Thereby, since it is not necessary for the passivation layer to have a predetermined thickness or more to prevent damage due to an etching process for forming the pixel electrodes, the thickness of the passivation layer is reduced

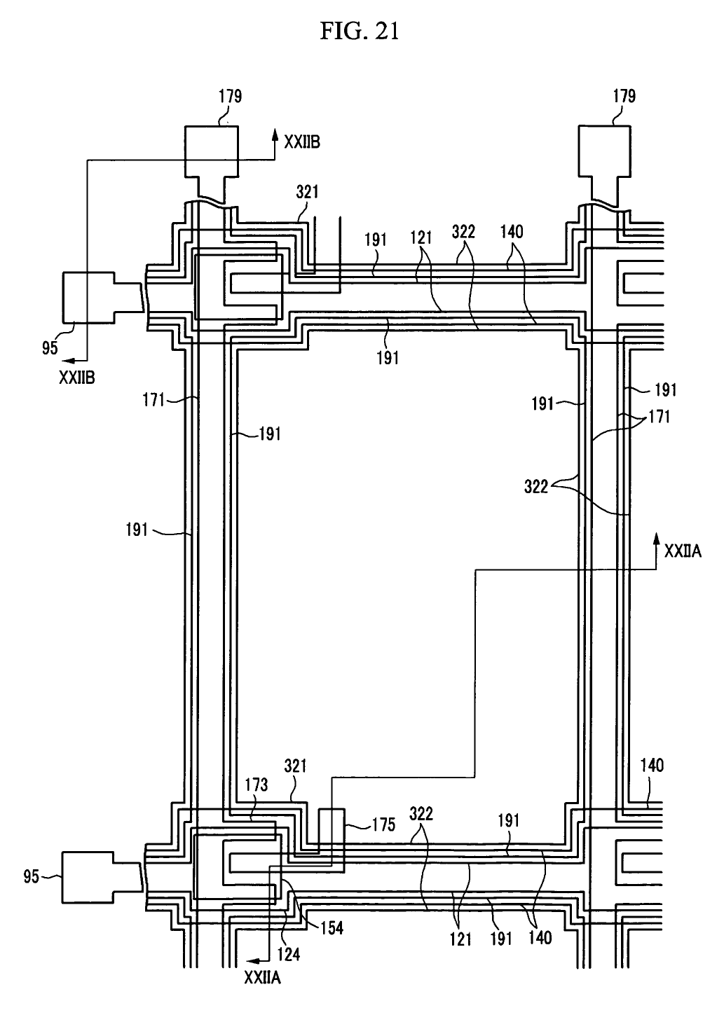

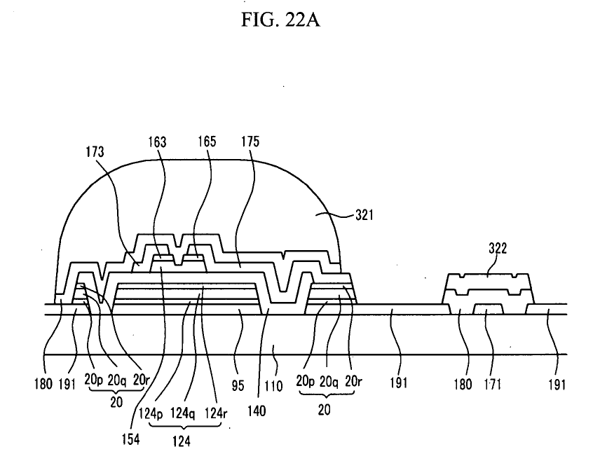

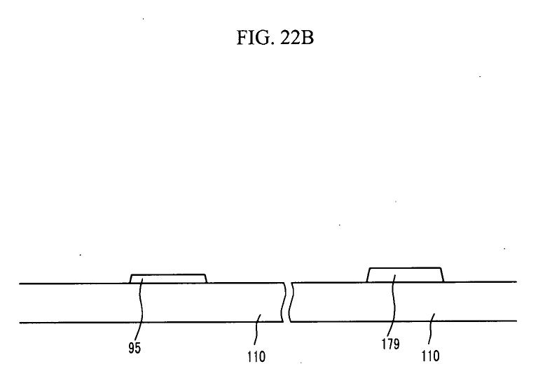

Next, a TFT array panel according to another exemplary embodiment of the present invention will be described in detail with reference to FIGS. 21 to 22B.

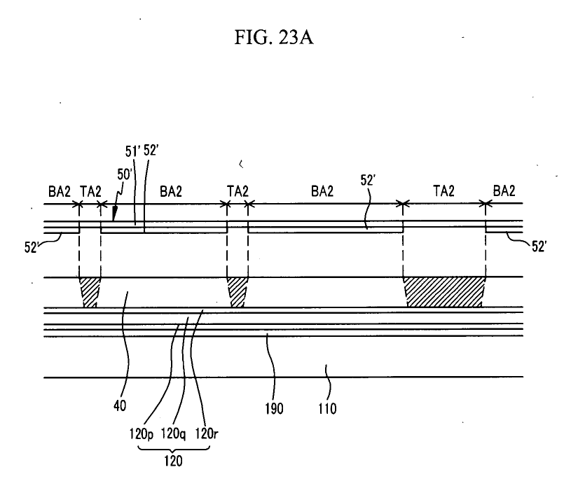

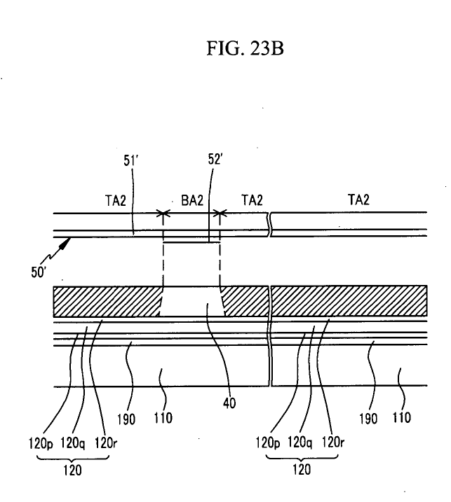

FIG. 21 is a layout view of a TFT array panel according to another exemplary embodiment of the present invention, and FIGS. 22A and 22B are sectional views of the TFT array panel shown in FIG. 21 taken along the lines XXIIA-XXIIA and XXIIB-XXIIB, respectively. Referring to FIGS. 22 to 23B, layered structures of a TFT array panel of this embodiment of the present invention are almost the same as those shown in FIGS. 1 to 2B.

That is, a plurality of pixel electrodes 191 and a plurality of transparent conductors 95 are formed on an insulating substrate 110. A plurality of gate insulating films 140, a plurality of semiconductor islands 154, and a plurality of ohmic contacts 163 and 165 are sequentially formed on pixel electrodes 191, the transparent conductors 95, and the exposed insulating substrate 110. A plurality of data lines including source electrodes 173 and a plurality of drain electrodes 175 are formed on the ohmic contacts 163 and 165, and a passivation layer 180 is formed on data lines 171 and drain electrodes 175. An insulating pattern 322 including a plurality of column spacers 321 is formed on passivation layer 180.

Unlike the TFT array panel shown in FIGS. 1 to 2B, portions of conductors 20p, 20q, and 20r are left on portions of pixel electrodes 191 overlapping gate insulating films 140 and drain electrodes 175.

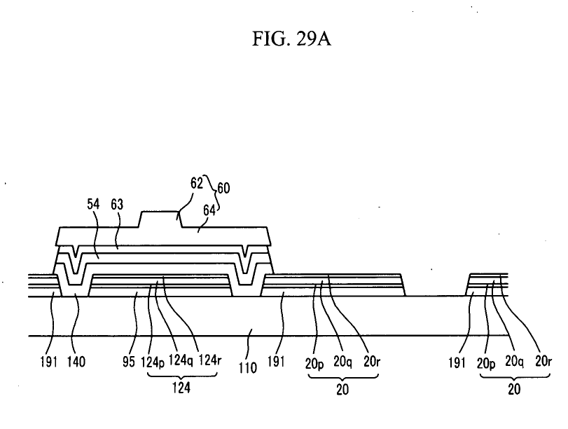

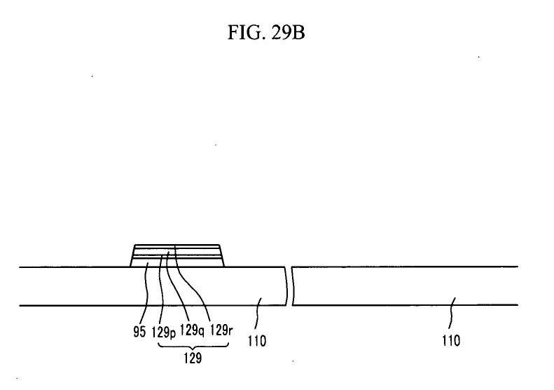

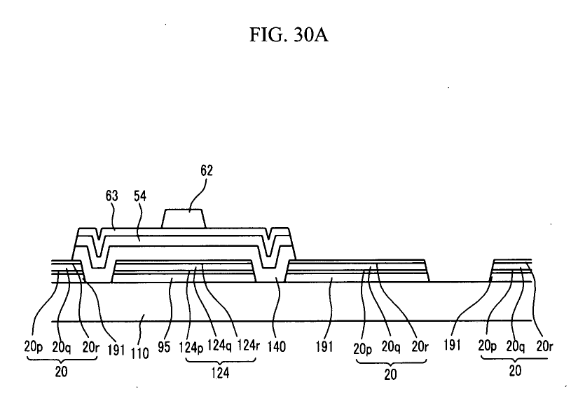

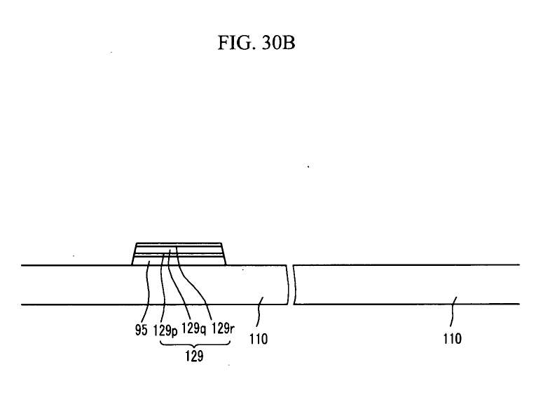

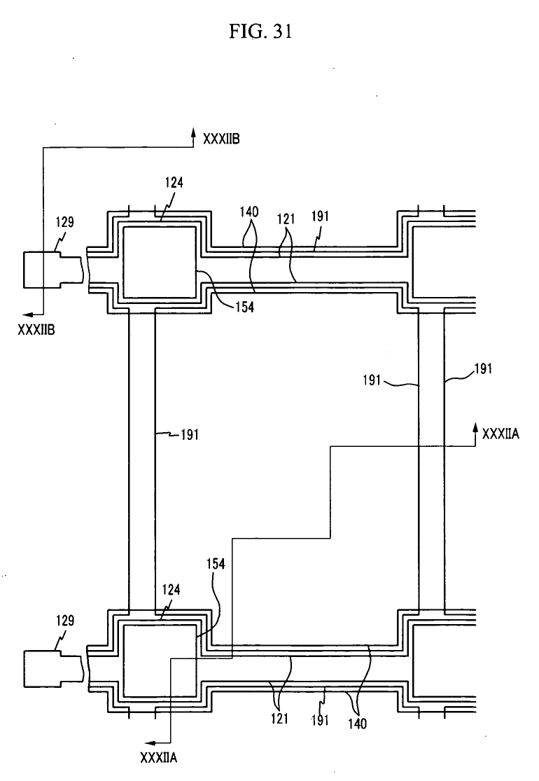

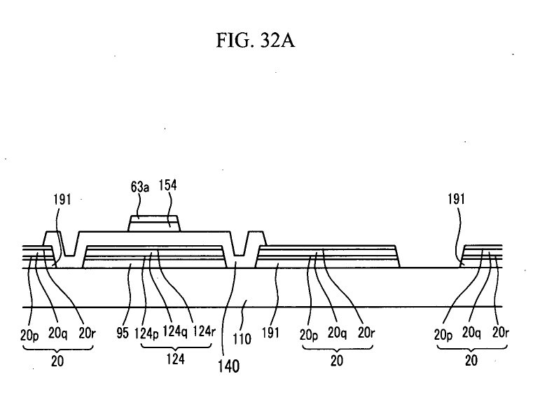

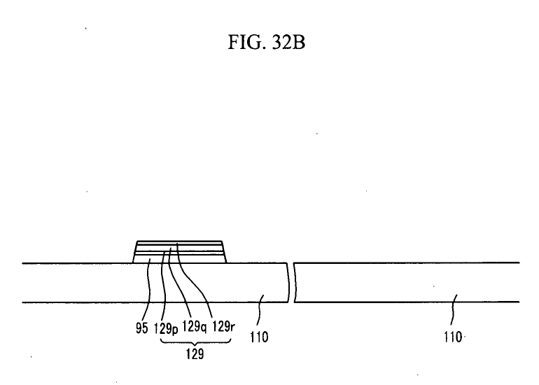

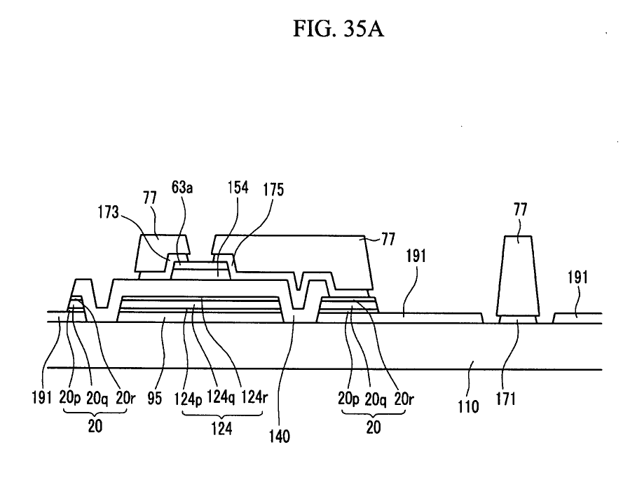

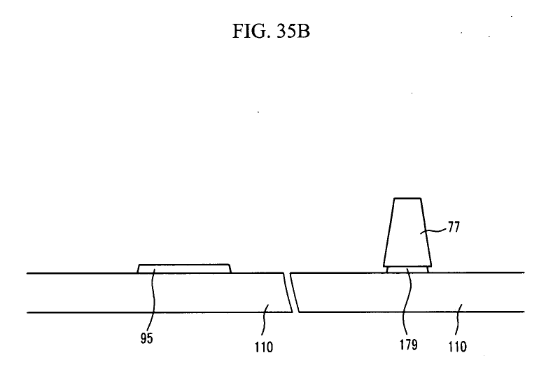

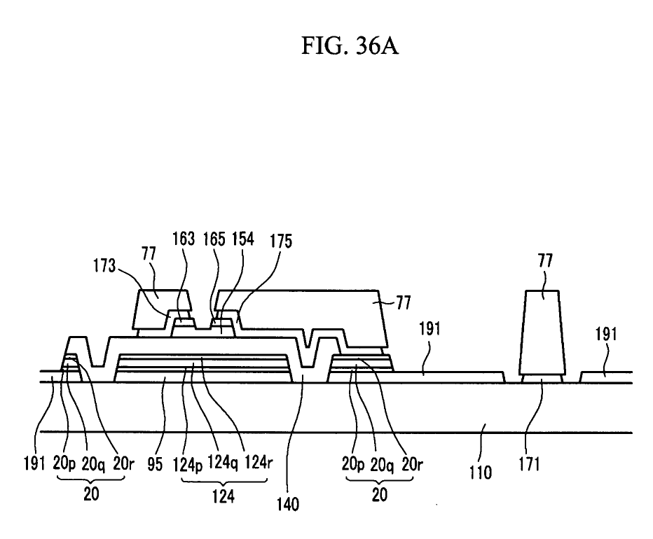

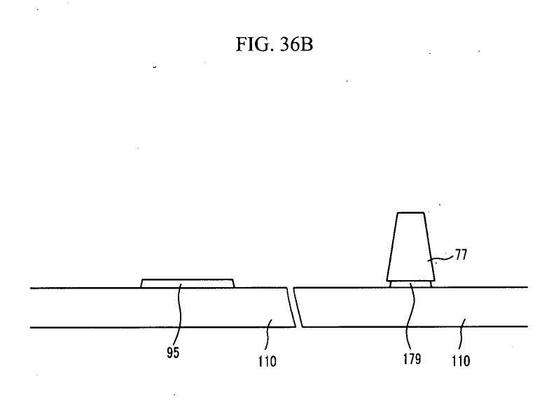

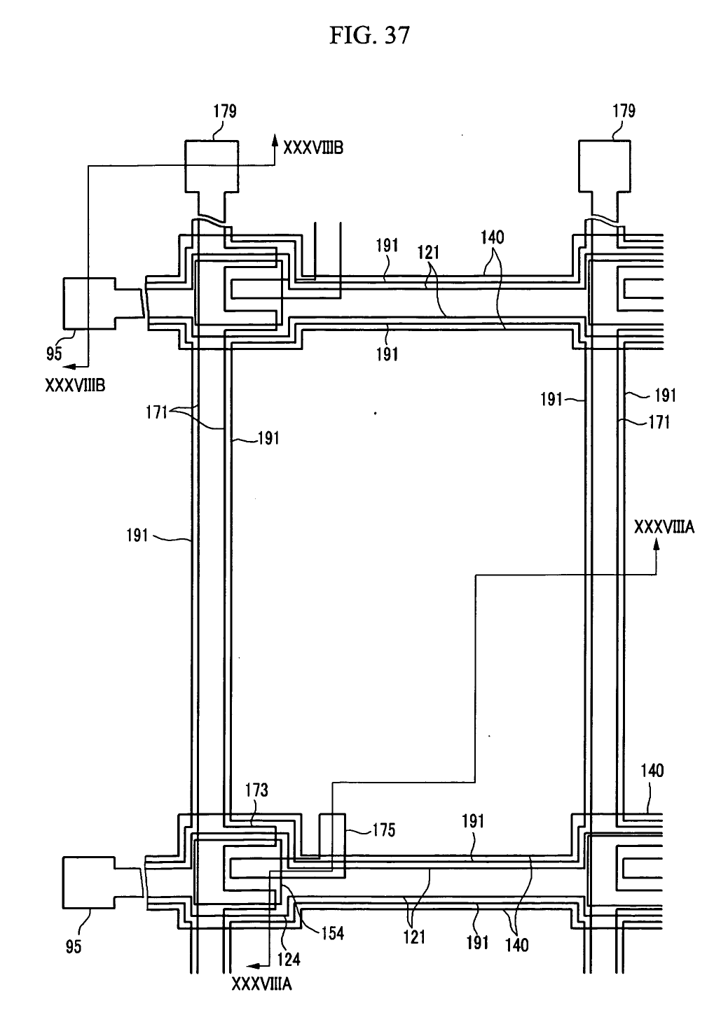

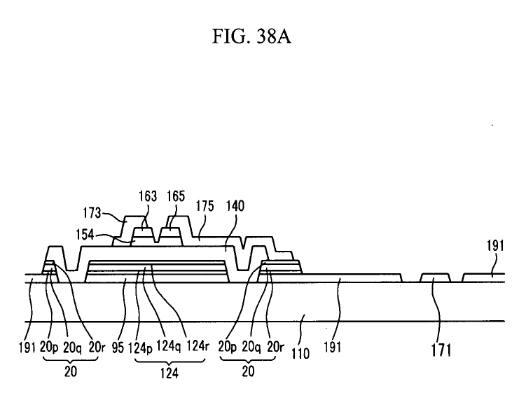

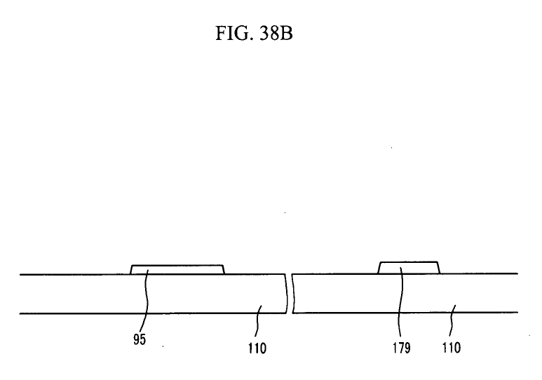

A manufacturing method of the TFT array panel according to other exemplary embodiments of the present invention will be described with reference to FIGS. 21 to 22B and 23A to 40B, as well as FIGS. 2A to 20B.

In the manufacturing method of the TFT array panel according to this embodiment of the present invention, conductors 20p, 20q, and 20r formed on pixel electrodes 191 are simultaneously removed while forming data lines 171 and drain electrodes 175.

That is, unlike FIGS. 3A and 3B, referring to FIGS. 23A and 23B, the translucent areas SA of the photo mask 50′, that is, portions facing pixel electrodes 191, are changed into light blocking areas BA2.

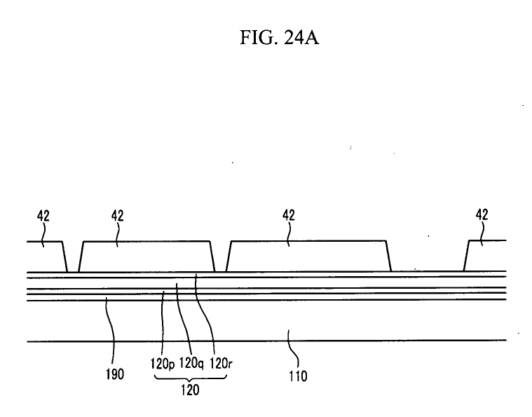

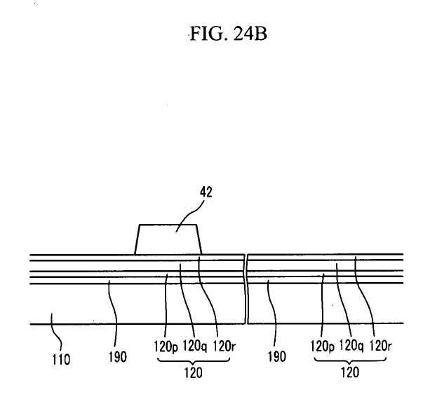

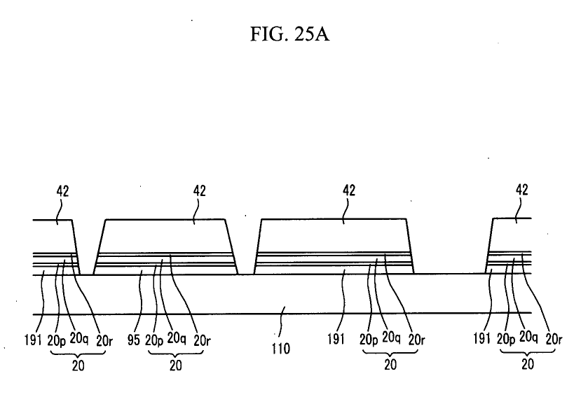

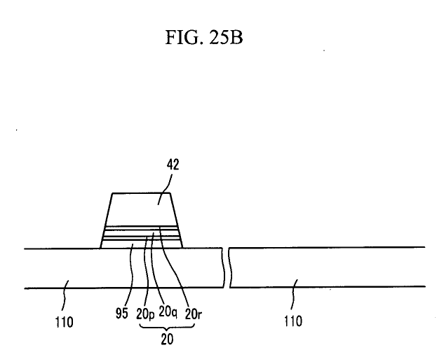

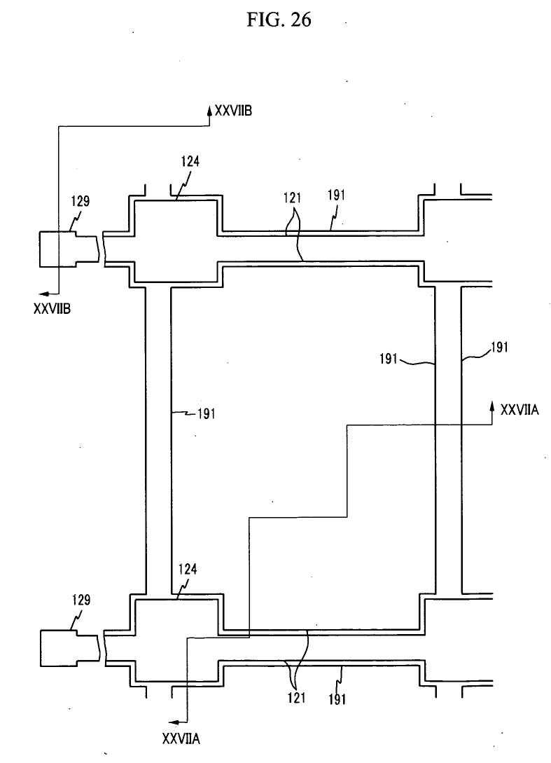

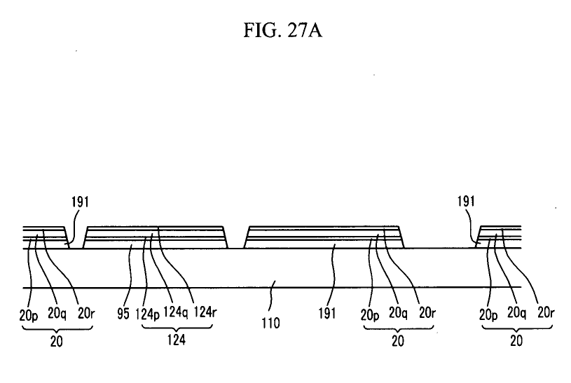

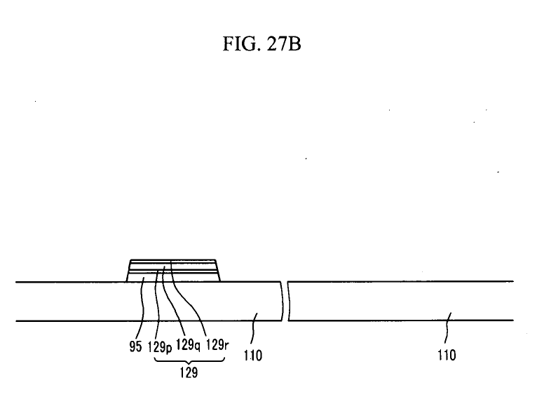

Then, referring to FIGS. 24A to 25B, photoresist 40 is exposed to light through photo mask 50′ and developed such that portions of photoresist 40 that have received a predetermined amount of light are removed. Next, an exposed conductive layer 120 is etched using the remaining photoresist 42 as an etch mask, and then a transparent conductive layer 190 is etched again using the remaining photoresist 42 as an etch mask to form a plurality of gate lines 121 including gate electrodes 124 and etched conductors 20p, 20q, and 20r, pixel electrodes 191 under the etched conductors 20p, 20q, and 20r, and transparent conductors 95 under gate lines 121, as shown in FIGS. 26A and 27B.

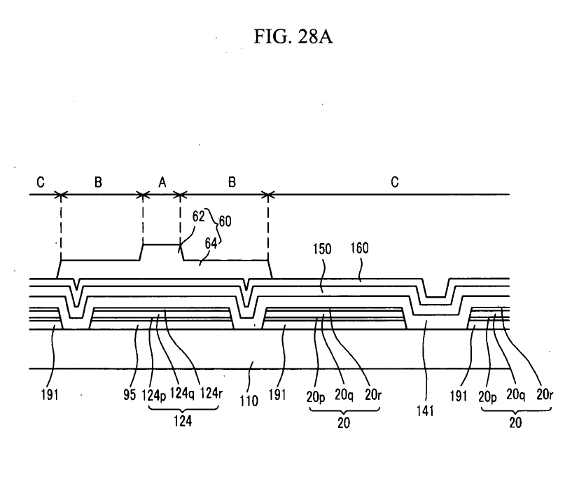

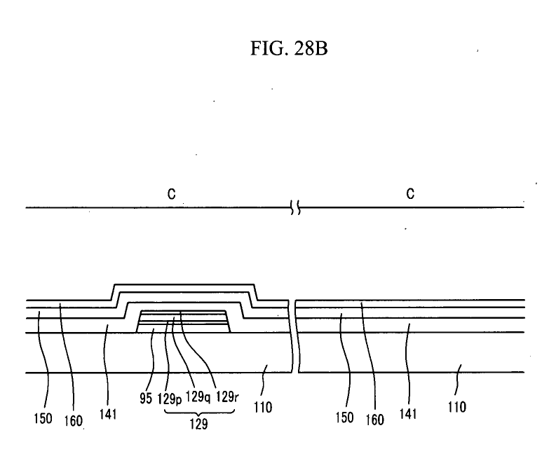

Referring to FIGS. 28A to 32B, a gate insulating layer 141, an intrinsic a-Si layer 150, and an extrinsic a-Si layer 160 are sequentially deposited by CVD to form a plurality of extrinsic a-Si islands 63, a plurality of semiconductor islands 154, and a plurality of gate insulating films 140 by using a photoresist 60.

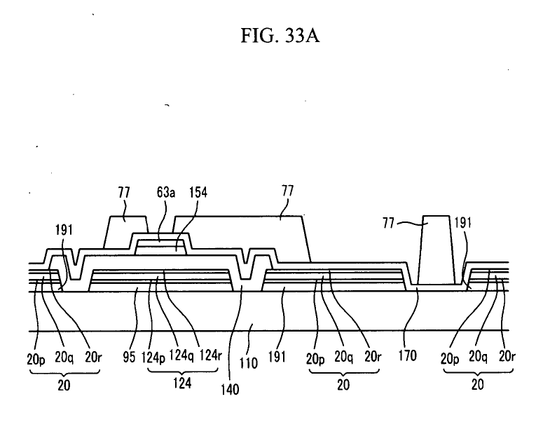

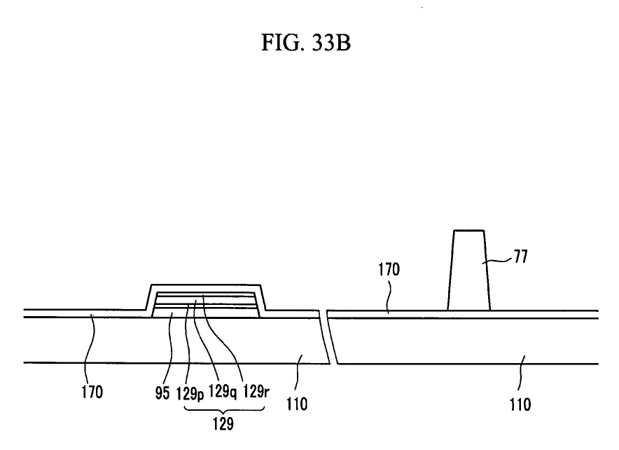

Next, referring to FIGS. 33 to 38B, a conductive layer 170 made of a material such as a metal, etc., is deposited and etched by wet etching, etc., to form a plurality of data lines 171 having source electrodes 173 and a plurality of drain electrodes 175. At this time, the underlying conductors 20p, 20q, 20r, 129p, 129q, and 129r are etched using drain electrodes 175 and gate insulating films 140 as an etch mask. Thereby, since the portions of the conductors 20p, 20q, 20r, 129p, 129q, and 129r formed on pixel electrodes 191 are removed, portions of pixel electrodes 191 and transparent conductor 95 are exposed except for portions overlapping drain electrodes 175 and gate insulating films 140.

Next, the exposed extrinsic a-Si islands 63 that are not covered with source electrodes 173 and drain electrodes 175 are removed, to form ohmic contact islands 163 and 165.

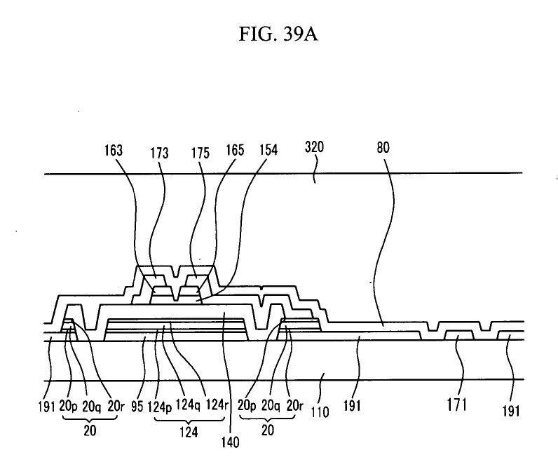

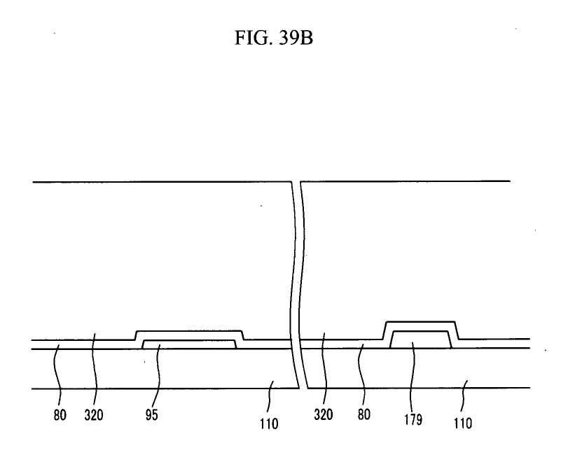

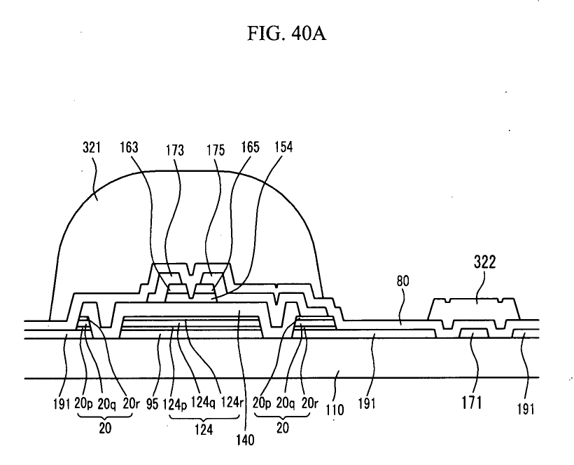

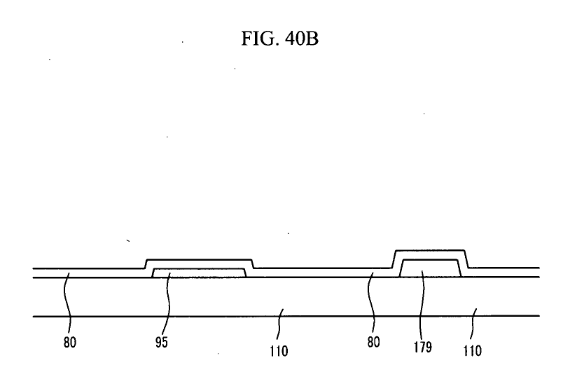

Next, referring to FIGS. 39A to 40B, like FIGS. 19A to 20B, a first insulating layer 80 and a second insulating layer 320 having photosensitivity are sequentially deposited and etched, to form an insulating pattern 322 including spacers 321 and a passivation layer 180 (refer to FIGS. 21 to 22B).

Like FIGS. 1 to 20B, pixel electrodes 191 are formed along with gate lines 121 using one mask, and thereby the number of manufacturing processes decreases and the manufacturing cost is reduced.

In addition, passivation layer 180 is formed using the spacers 321, and thereby the number of manufacturing processes decreases and the manufacturing cost is reduced. Furthermore, since pixel electrodes 191 are formed under passivation layer 180, a thickness of passivation layer 180 becomes thin.

Referring to FIGS. 9A and 9B, gate insulating films 140, etc., formed on pixel electrodes 191 are formed under the low temperature such as about 240 to 280° C. for preventing damage of the underlying pixel electrodes 191. However, in this embodiment of the present invention, gate insulating films 140, etc., formed on pixel electrodes 191 may be formed under a high temperature such as about 320 to 360° C. without damage to pixel electrodes 191 because gate lines 121 formed on pixel electrodes 191 function as shielding members. Thereby, a transmittance reduction of pixel electrodes 191 and deterioration of image quality are prevented.

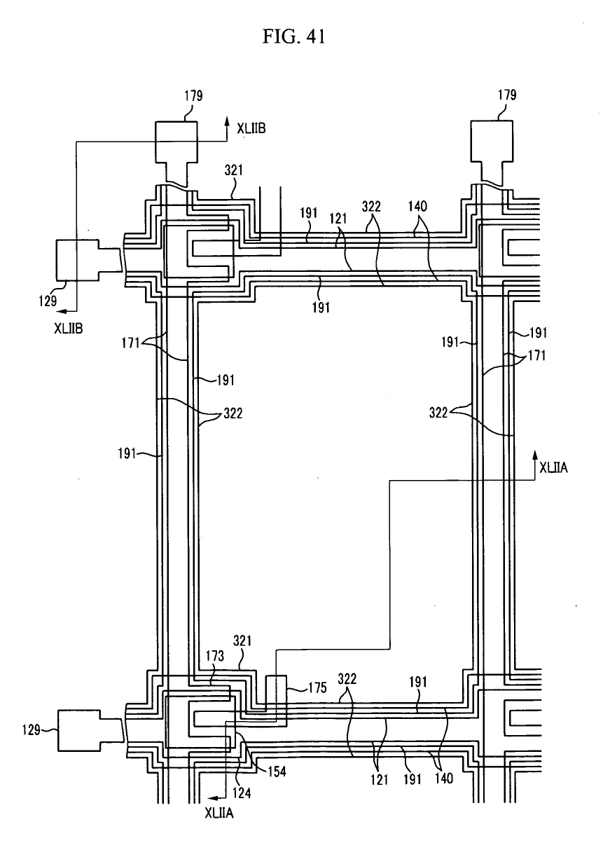

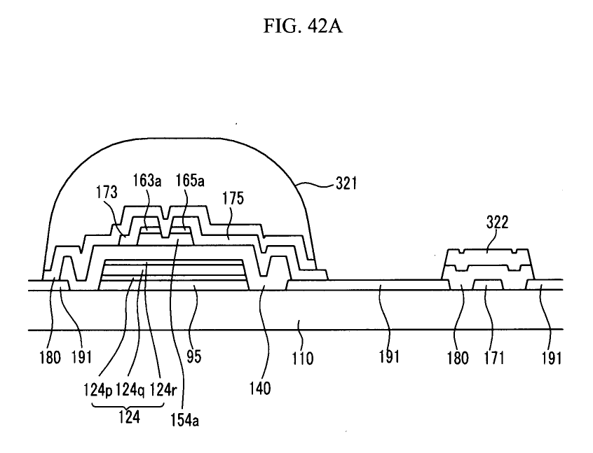

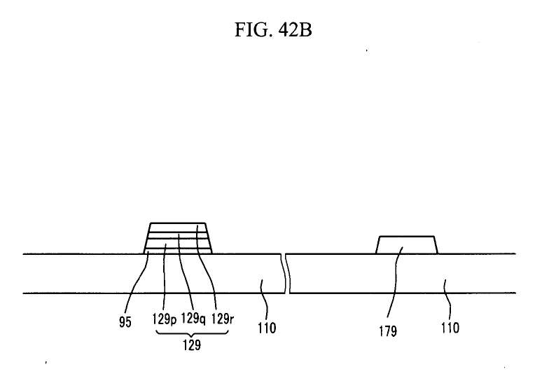

Next, referring to FIGS. 41 to 42B, a thin transistor panel according to further another embodiment of the present invention will be described.

Layered structures of the TFT array panel according to this embodiment are almost the same as those shown in FIGS. 1 to 2B except that the boundaries of the contact assistants 163a and 165a and the underlying semiconductors 154a are the same as those the overlying source electrodes 173a and drain electrodes 175.

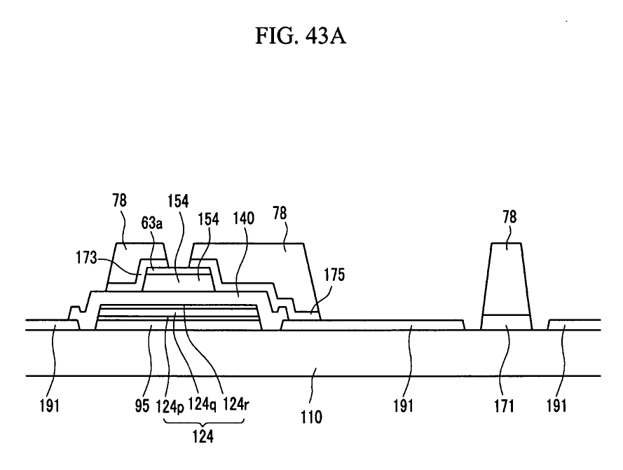

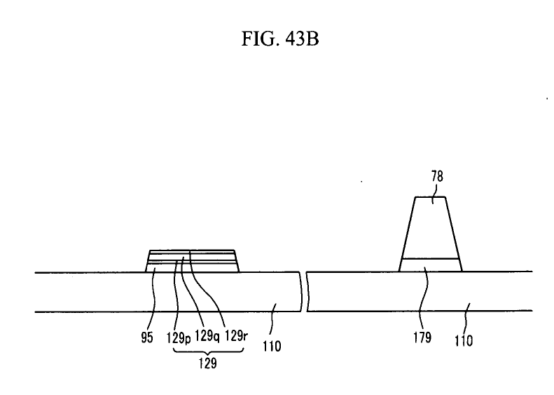

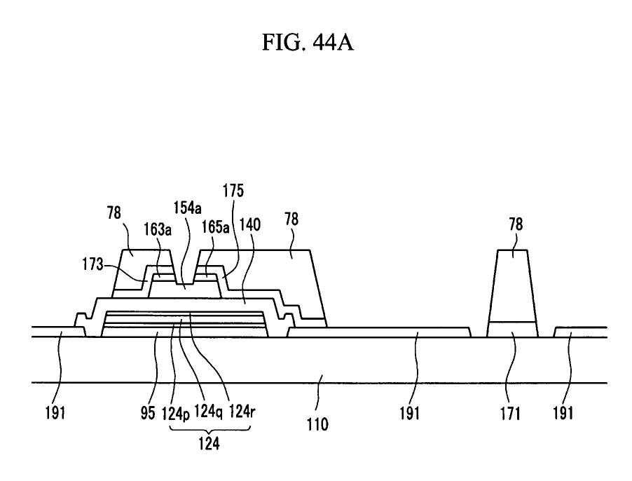

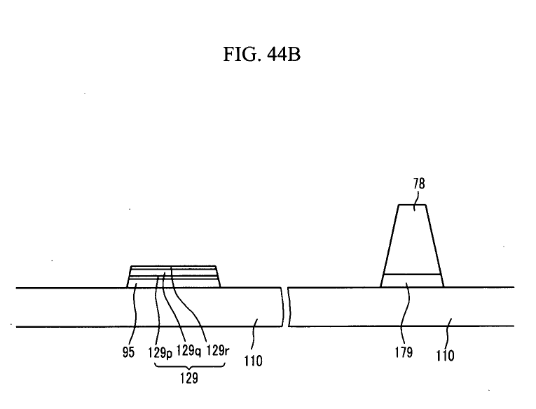

A method of manufacturing the TFT array panel will be described FIGS. 43A to 44B as well as FIGS. 3A to 15b and 41 to 42B.

As shown in FIGS. 3A to 13B, a plurality of pixel electrodes 191 and a plurality of transparent conductors 95 are formed on a substrate 110, a plurality of gate insulating films 140 are formed on pixel electrodes 191 and the transparent conductors 95, and then a plurality of semiconductor islands 154 and a plurality of extrinsic a-Si islands 63 are formed. As shown in FIGS. 14A to 15B, after depositing conductive layer 170 on semiconductor islands 154 and the extrinsic a-Si islands 63, the exposed conductive layer 170 are etched using a photoresist portions 77 as an etch mask to form a plurality of data lines 171 including source electrodes 173 and a plurality of drain electrodes 175.

As shown in FIGS. 43A and 43B, by using an etch-back process, etc., undercut portions of the photoresist portions 77 are removed to form photoresist portions 78 having reduced thicknesses and boundaries that are the same as those of the underlying data lines 171 and drain electrodes 175.

Next, referring to FIGS. 44A and 44B, the exposed extrinsic a-Si islands 63 are removed using the photoresist portions 78 as an etch mask to form a plurality of ohmic contacts 163a and 165a, and then the photoresist portions 78 are removed. Thereby, the boundaries of data lines 171 and drain electrodes 175 are the same as those of the ohmic contacts 163a and 165a and the semiconductors 154a thereunder. As shown in FIGS. 19A to 20B, a first insulating layer 80 and a second insulating layer 320 are sequentially deposited and etched to form an insulating pattern 322 including a plurality of column spacers 321 and a passivation layer 180 (refer to FIGS. 41 to 42B).

According to the embodiment, advantages described above are obtained. Further, reduction of an aperture ratio due to the projected ohmic contacts is decreased. In addition, and abnormal current flows or interferences of currents due to the projected ohmic contacts and the underlying semiconductors in channel portions are reduced, and thereby characteristic variations of the TFT transistors, which are caused by the channel portions abnormally formed are reduced. Light leakage occurred near the projected ohmic contacts and the semiconductors is reduced such that image deterioration such as an afterimage decreased.

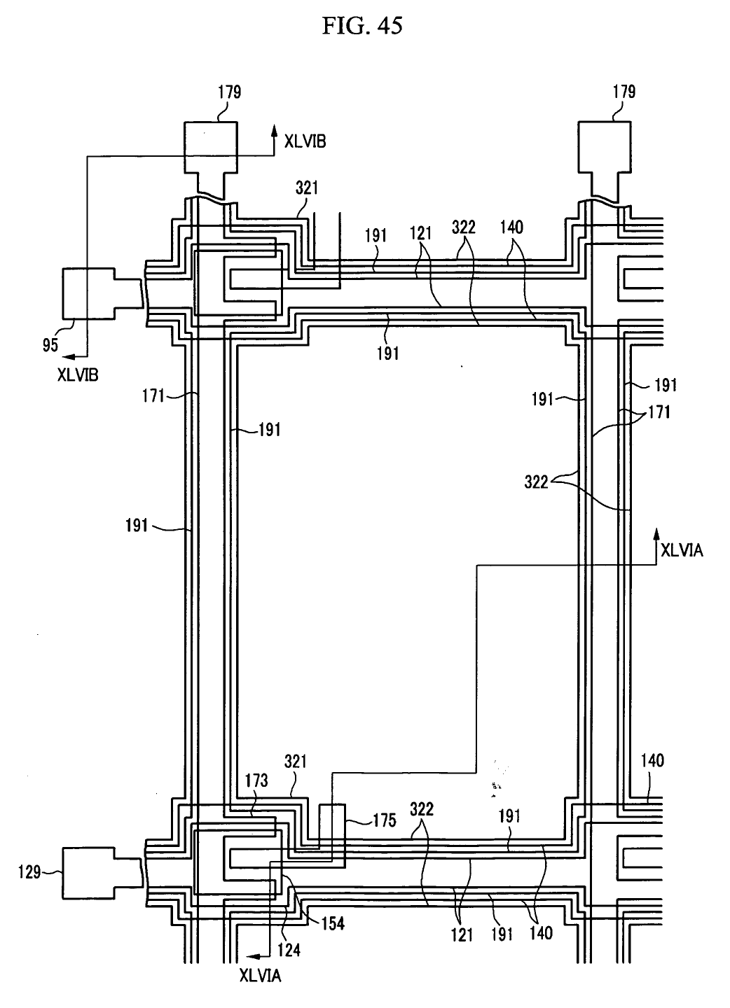

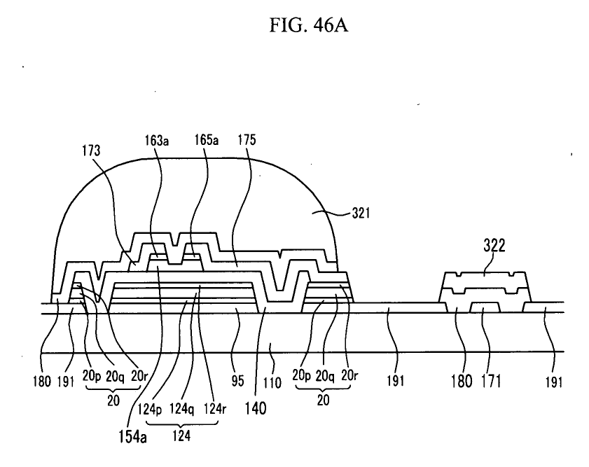

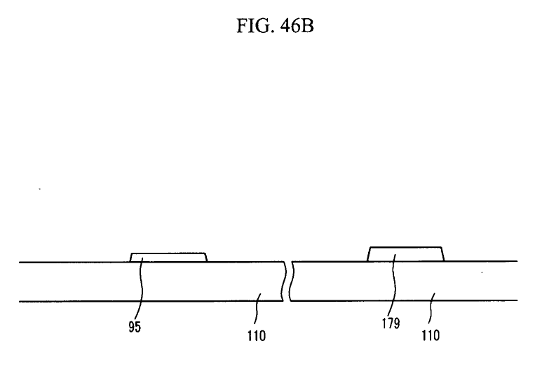

Next, a TFT array panel according to further another embodiment will be described referring to FIGS. 45 to 46B.

Layered structures of the TFT array panel according to this embodiment are almost the same as those shown in FIGS. 21 to 22B except that the boundaries of the contact assistants 163a and 165a and the underlying semiconductors 154a are the same as those the overlying source electrodes 173a and drain electrodes 175.

A method of manufacturing the TFT array panel will be described with reference to FIGS. 23A to 34B as well as FIGS. 45 to 46B and FIGS. 47A to 48B.

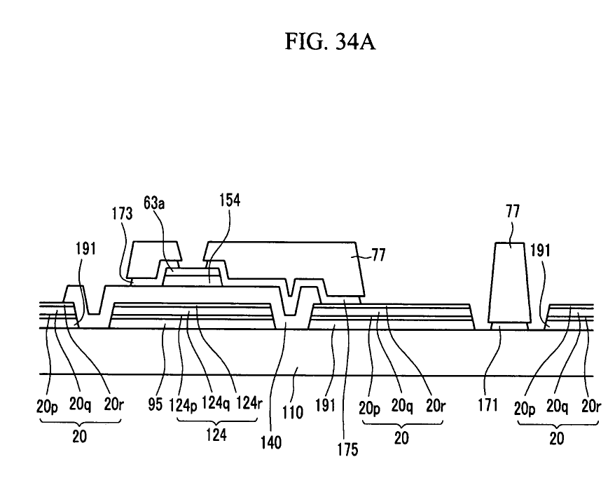

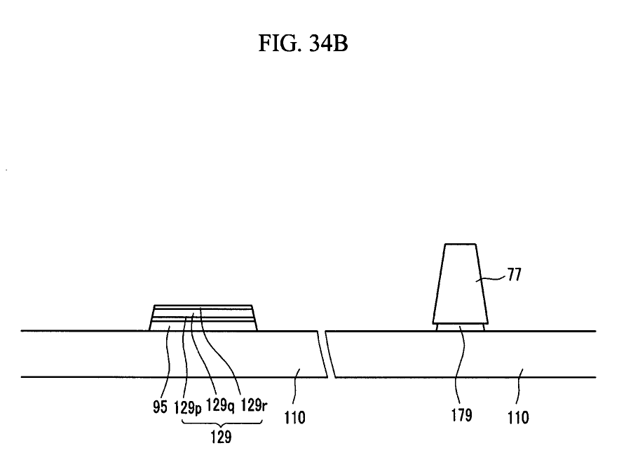

As shown in FIGS. 23A to 27B, a plurality of gate lines including gate electrodes 124, etched conductors 20p, 20q, and 20r, a plurality of pixel electrodes 191, and a plurality of transparent conductors 95 are formed on a substrate 110, and, as shown in FIGS. 28A to 32B, a plurality of extrinsic a-Si islands 63, a plurality of semiconductor islands 154a, and a plurality of gate insulating films 140 are formed. As shown in FIGS. 33A to 34B, after depositing conductive layer 170 on semiconductor islands 154a and the extrinsic a-Si islands 63, the exposed conductive layer 170 are etched using a photoresist portions 77 as an etch mask to form a plurality of data lines 171including source electrodes 173 and a plurality of drain electrodes 175.

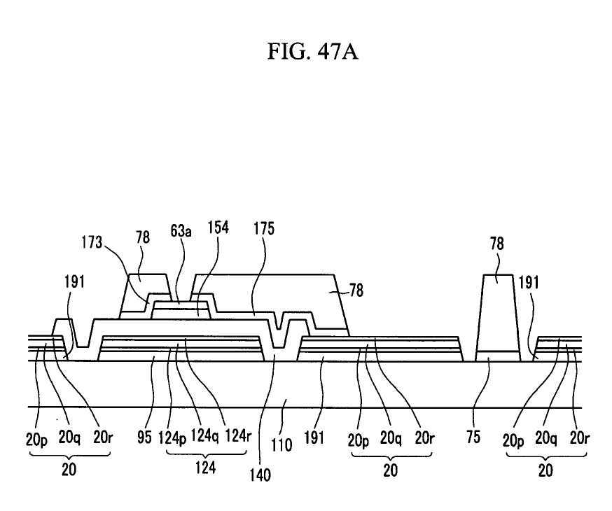

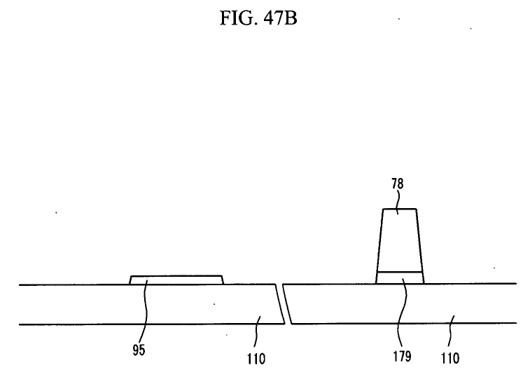

Referring to FIGS. 47A and 47B, by using an etch-back process, etc., undercut portions of the photoresist portions 77 are removed to form photoresist portions 78 having reduced thicknesses and boundaries that are the same as those of the underlying data lines 171 and drain electrodes 175.

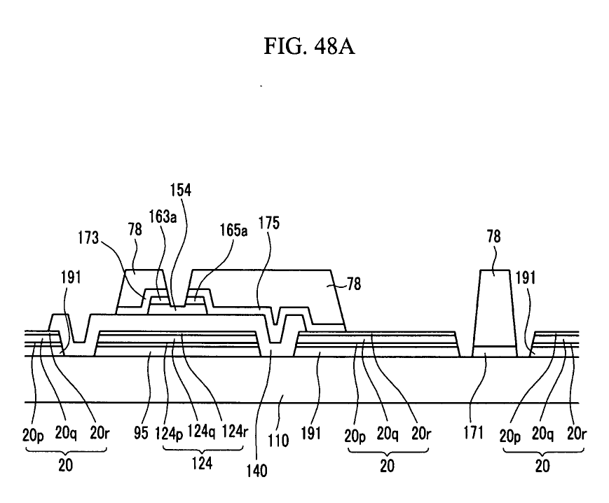

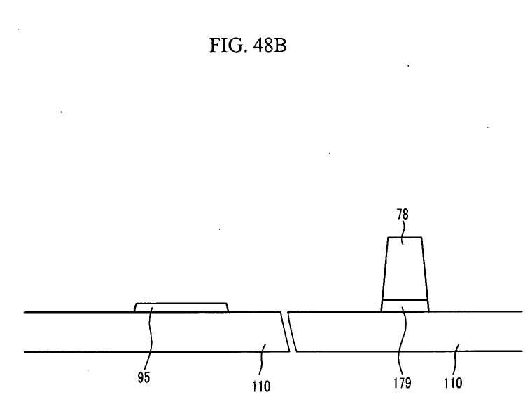

Referring to FIGS. 48A and 48B, the exposed extrinsic a-Si islands 63 are removed using the photoresist portions 78 as an etch mask to form a plurality of ohmic contacts 163a and 165a, and then the photoresist portions 78 are removed. Thereby, the boundaries of data lines 171 and drain electrodes 175 are the same as those of the ohmic contacts 163a and 165a and the semiconductors 154a thereunder. As shown in FIGS. 39A to 40B, a first insulating layer 80 and a second insulating layer 320 are sequentially deposited and etched to form an insulating pattern 322 including a plurality of column spacers 321 and a passivation layer 180 (refer to FIGS. 45 to 46B).

According to the embodiment, advantages described above are obtained. Further, the advantages described with reference to FIGS. 41 to 44B, that is, the reduction of an aperture ratio is decreased, the abnormal current flows or the interferences are reduced, and the stable operation of the TFT is obtained. In addition, the image deterioration due to the light leakage, etc. is reduced.

In embodiments of the present invention, gate insulating films 140 are formed along gate lines 121 in the transverse direction, but may be formed along data lines 171 as well as gate lines 121.

According to the present invention, the pixel electrodes are formed along with the gate lines using one mask, and thereby the number of manufacturing processes decreases and the manufacturing cost is reduced. Moreover, since the pixel electrodes are formed under the passivation layer, a thickness of the passivation layer becomes thin.

Furthermore, the passivation layer is formed using the spacers, and thereby the number of manufacturing processes decreases and the manufacturing cost is reduced.

In addition, the gate insulating layer, etc., formed on the pixel electrodes are formed under a high temperature such as about 320 to 360° C. without damage to the pixel electrodes because the conductors formed on the pixel electrodes are removed in forming the data lines and the drain electrodes. Thereby, a transmittance reduction of the pixel electrodes and deterioration of image quality are prevented, and the number of manufacturing processes is decreased.

Moreover, since the boundaries of the data lines and drain electrodes 175 is the same as those of the ohmic contacts and the underlying semiconductors, the reduction of an aperture ratio is decreased, the abnormal current flows or the interferences are reduced, and the stable operation of the TFT is obtained. In addition, the image deterioration due to the light leakage, etc. is reduced.

While this invention has been described in connection with what is presently considered to be practical exemplary embodiments, it is to be understood that various modifications and equivalent arrangements will be apparent to those skilled in the art and may be made without, however, departing from the spirit and scope of the invention.

What is claimed is:

1. A thin film transistor (TFT) array panel comprising:
a pixel electrode formed on a substrate;
a gate line formed on the substrate;
a gate insulating film formed on the gate line;
a semiconductor formed on the gate insulating film;
a data line and a drain electrode formed on the gate insulating film; and
a passivation layer formed on portions of the data line and the drain electrode,
wherein the gate line comprises a first film formed on the same layer and with the same material as the pixel electrode and a second film formed on the first film.

2. The TFT array panel of claim 1, wherein the pixel electrode comprises a transparent conductive material.

3. The TFT array panel of claim 1, wherein the second film of the gate line comprises a first layer made of Mo (alloy), a second layer formed on the first layer and made of Al (alloy), and a third layer formed on the second layer and made of Mo (alloy).

4. The TFT array panel of claim 1, wherein the gate insulating film overlaps a portion of an edge of the pixel electrode.

5. The TFT array panel of claim 2, wherein the passivation layer overlaps a portion of an edge of the pixel electrode.

6. The TFT array panel of claim 2, further comprising an insulating pattern including a column spacer and formed on the passivation layer.

7. The TFT array panel of claim 6, wherein the passivation layer has a planar shape that is substantially the same as that of the insulating pattern.

8. A thin film transistor (TFT) array panel comprising:
a pixel electrode formed on a substrate;
a gate line formed on the substrate;
a gate insulating film formed on the gate line;
a semiconductor formed on the gate insulating film;
a data line and a drain electrode formed on the gate insulating film; and
a passivation layer formed on portions of the data line and the drain electrode,
wherein the gate line comprises a first film formed on the same layer and with the same material as the pixel electrode and a second film formed on the first film, and an overlapping portion of the drain electrode and the pixel electrode further comprise a conductor made of the same material as the gate line.

9. The TFT array panel of claim 8, wherein the pixel electrode comprises a transparent conductive material.

10. The TFT array panel of claim 8, wherein the second film of the gate line comprises a first layer made of Mo (alloy), a second layer formed on the first layer and made of Al (alloy), and a third layer formed on the second layer and made of Mo (alloy).

11. The TFT array panel of claim 8, wherein the gate insulating film overlaps a portion of an edge of the pixel electrode.

12. The TFT array panel of claim 8, wherein the passivation layer overlaps a portion of an edge of the pixel electrode.

13. The TFT array panel of claim 8, further comprising an insulating pattern including a column spacer and formed on the passivation layer.

14. The TFT array panel of claim 13, wherein the passivation layer has a planar shape that is substantially the same as that of the insulating pattern.

15. A manufacturing a thin film transistor array panel, comprising:
forming a transparent conductive layer on a substrate;
forming a conductive layer on the transparent conductive layer;
a forming a first photoresist on the conductive layer;
etching the conductive layer with a first etchant using the first photoresist as a mask;
etching the transparent conductive layer with a second etchant that is different from the first etchant using the first photoresist as a mask to form a pixel electrode;
varying the first photoresist to form a second photoresist;
removing the exposed conductive layer with the first etchant using the second photoresist as a mask to form a gate line;
forming a gate insulating film on the gate line and the pixel electrode;
forming a semiconductor on the gate insulating film;
forming a data line and a drain electrode on the semiconductor;
forming a first insulating layer and a second insulating layer on the data line and the drain electrode;
exposing the second insulating layer to light to form an insulating pattern including a spacer; and
etching the first insulating layer using the insulating pattern as a mask to form a passivation layer.

16. The method of claim 15, wherein the first etchant is an integrated etchant.

17. The method of claim 15, wherein the second etchant is a pixel integrated etchant.

18. The method of claim 15, wherein the first photoresist is formed by a photo mask including a light blocking area, a translucent area, and a light transmitting area.

19. The method of claim 15, wherein the formation of the second photoresist comprises an ashing process.

20. The method of claim 15, wherein the semiconductor comprises a first semiconductor layer and a second semiconductor layer formed on the first semiconductor layer.

21. The method of claim 20, wherein the formation of the gate insulating film, the formation of the semiconductor, and the formation of the data line and the drain electrode comprises:
depositing a gate insulating layer, an intrinsic a-Si layer, and an extrinsic a-Si layer on the pixel electrodes;
forming a third photoresist on the extrinsic a-Si layer;
sequentially etching the extrinsic a-Si layer, the intrinsic a-Si layer, and the gate insulating layer to form the gate insulating film;
changing the third photoresist to form a fourth photoresist;
etching the extrinsic a-Si layer and the intrinsic a-Si layer using the fourth photoresist as a mask to form the first semiconductor layer;
forming a data conductive layer on the exposed pixel electrodes, the exposed gate insulating film, and the exposed extrinsic a-Si layer;
forming a fifth photoresist on the data conductive layer;
removing the exposed data conductive layer using the fifth photoresist as a mask to form the data line and the electrode line; and
etching the exposed extrinsic a-Si layer using the fifth photoresist as a mask to form the second semiconductor layer.

22. The method of claim 21, wherein the formation of the data line and the drain electrode comprises removing the portions of the fifth photoresist projected from the data line and the drain electrode.

23. A manufacturing method of a thin film transistor array panel, the method comprising:
forming a transparent conductive layer on a substrate;
forming a first conductive layer on the transparent conductive layer;
forming a photoresist on the first conductive layer;
etching the first conductive layer with a first etchant using the photoresist as a mask;
etching the transparent conductive layer with a second etchant that is different from the first etchant using the photoresist as a mask to form a gate pattern including a gate line;
forming a gate insulating film on the gate pattern;
forming a semiconductor layer on the gate insulating film;
forming a second conductive layer on the semiconductor;
etching the second conductive layer and the exposed gate pattern to form a data line, a drain electrode, and a pixel electrode;
forming a first insulating layer and a second insulating layer on the data line, the drain electrode, and the pixel electrode;
exposing the second insulating layer to light to form an insulating pattern including a spacer; and
etching the first insulating layer using the insulating pattern as a mask to form a passivation layer.

24. The method of claim 23, wherein the first etchant is an integrated etchant.

25. The method of claim 24, wherein the second etchant is a pixel integrated etchant.

26. The method of claim 23, wherein the photoresist is formed by an photo mask including a light blocking area, a translucent area, and a light transmitting area.

27. The method of claim 23, wherein the semiconductor comprises a first semiconductor layer and a second semiconductor layer formed on the first semiconductor layer.

28. The method of claim 27, wherein the formation of the gate insulating film, the formation of the semiconductor, and the formation of the data line and the drain electrode comprises:
depositing a gate insulating layer, an intrinsic a-Si layer, and an extrinsic a-Si layer on the pixel electrodes;
forming a third photoresist on the extrinsic a-Si layer;
sequentially etching the extrinsic a-Si layer, the intrinsic a-Si layer, and the gate insulating layer to form the gate insulating film;
changing the third photoresist to form a fourth photoresist;
etching the extrinsic a-Si layer and the intrinsic a-Si layer using the fourth photoresist as a mask to form the first semiconductor layer;
forming a data conductive layer on the exposed pixel electrodes, the exposed gate insulating film, and the exposed extrinsic a-Si layer;
forming a fifth photoresist on the data conductive layer;
removing the exposed data conductive layer using the fifth photoresist as a mask to form the data line and the electrode line; and
etching the exposed extrinsic a-Si layer using the fifth photoresist as a mask to form the second semiconductor layer.

29. The method of claim 21, wherein the formation of the data line and the drain electrode comprises removing the portions of the fifth photoresist projected from the data line and the drain electrode.

30. A manufacturing method of a thin film transistor array panel, the method comprising:
forming a transparent conductive layer on a substrate;
forming a conductive layer on the transparent conductive layer;
forming a first photoresist on the conductive layer;
etching the conductive layer and the transparent conductive layer with one etchant using the first photoresist as a mask to form a pixel electrode;
varying the first photoresist to form a second photoresist;
removing the exposed conductive layer using the second photoresist as a mask to form a gate line;
forming a gate insulating film on the gate line and the pixel electrode;
forming a semiconductor layer on the gate insulating film;
forming a data line and a drain electrode on the semiconductor;
forming a first insulating layer and a second insulating layer on the data line and the drain electrode;
exposing the second insulating layer to light to form an insulating pattern including a spacer; and
etching the first insulating layer using the insulating pattern as a mask to form a passivation layer.

31. A manufacturing method of a thin film transistor array panel, the method comprising:
forming a transparent conductive layer on a substrate;
forming a first conductive layer on the transparent conductive layer;
forming a photoresist on the first conductive layer;
etching the first conductive layer and the transparent conductive layer with one etchant using the photoresist as a mask to form a gate pattern including a gate line;
forming a gate insulating film on the gate pattern;
forming a semiconductor layer on the gate insulating film;
forming a second conductive layer on the semiconductor;
etching the second conductive layer and the exposed gate pattern to form a data line, a drain electrode, and a pixel electrode;
forming a first insulating layer and a second insulating layer on the data line, the drain electrode, and the pixel electrode;
exposing the second insulating layer to light to form an insulating pattern including a spacer; and
etching the first insulating layer using the insulating pattern as a mask to form a passivation layer.
